(19) United States
(12) Patent Application Publication
(10) Pub. No.: US 2026/0271710 A1
(43) Pub. Date: Sep. 10, 2026

(54) SEMICONDUCTOR DEVICE AND VEHICLE

(71) Applicant: ROHM CO., LTD., Kyoto-shi (JP)

(72) Inventors: Masashi HAYASHIGUCHI, Kyoto-shi (JP); Hidetoshi ABE, Kyoto-shi (JP); Yoshihisa TSUKAMOTO, Kyoto-shi (JP); Hideki SAWADA, Kyoto-shi (JP)

(21) Appl. No.: 19/665,738

(22) Filed: May 1, 2026

Related U.S. Application Data
(63) Continuation of application No. PCT/JP2024/038172, filed on Oct. 25, 2024.

(30) Foreign Application Priority Data
Nov. 8, 2023 (JP) 2023-190544

(51) Int. Cl. H10W 40/22; H10W 40/20; H10W 40/40; H10W 70/40; H10W 74/10; H10W 90/00; H10W 90/10; H10W 90/22

(52) U.S. Cl. CPC H10W 40/228; H10W 40/233; H10W 40/40; H10W 70/461; H10W 74/121; H10W 90/10; H10W 90/726; H10W 90/22

(57) ABSTRACT

A semiconductor device includes a first semiconductor element including a first electrode located on one side in a first direction, a first terminal facing the first electrode, a first pillar electrically connected to the first electrode, and a first heat dissipation member electrically connected to the first terminal. A first flow path is provided between the first semiconductor element and the first terminal in the first direction. The first pillar and the first heat dissipation member are housed in the first flow path. The first heat dissipation member is conductively bonded to the first pillar.

### TECHNICAL FIELD

The present disclosure relates to a semiconductor device and a vehicle equipped with the semiconductor device.

### BACKGROUND ART

WO 2017/094370 discloses an example of a semiconductor module including a semiconductor device and a cooler. The cooler includes a housing having a hollow region, and a heat dissipator. The housing has an opening communicating with the hollow region. The heat dissipator is attached to the housing so as to close the opening. A part of the heat dissipator is housed in the hollow region. The semiconductor device is bonded to the portion of the heat dissipator that protrudes from the hollow region to the exterior. When coolant (such as cooling water) is circulated through the hollow region, the coolant comes into contact with the heat dissipator. Thus, the semiconductor device can be efficiently cooled via the heat dissipator.

However, in the configuration of the semiconductor module disclosed in WO 2017/094370, the cooling effect on the semiconductor device is not sufficiently achieved relative to the scale of the cooler.

### BRIEF DESCRIPTION OF THE DRAWINGS

FIG. 1 is a plan view of a semiconductor device according to a first embodiment of the present disclosure.

FIG. 2 is a plan view corresponding to FIG. 1, as seen through a housing.

FIG. 3 is a plan view corresponding to FIG. 2, in which illustration of a third terminal, a plurality of third heat dissipation members, and a plurality of fourth heat dissipation members is omitted.

FIG. 4 is a plan view corresponding to FIG. 3, in which illustration of a third signal terminal, a fourth signal terminal, a plurality of second semiconductor elements, a plurality of second protective layers, a plurality of third pillars, a plurality of fourth pillars, a plurality of second gate pillars, a plurality of second detection pillars, a plurality of third leads, and a plurality of fourth leads is omitted.

FIG. 5 is a plan view corresponding to FIG. 4, in which illustration of a first terminal and a plurality of first heat dissipation members is omitted.

FIG. 6 is a bottom view of the semiconductor device shown in FIG. 1.

FIG. 7 is a sectional view taken along line VII-VII in FIG. 3.

FIG. 8 is a sectional view taken along line VIII-VIII in FIG. 3.

FIG. 9 is a sectional view taken along line IX-IX in FIG. 3.

FIG. 10 is a partial enlarged view of FIG. 7.

FIG. 11 is a partial enlarged view of FIG. 8, showing one of a plurality of first semiconductor elements and the surrounding area.

FIG. 12 is a partial enlarged view of FIG. 8, showing one of the plurality of second semiconductor element and the nearby portion.

FIG. 13 is a sectional view showing a state in which a coolant flows down in the semiconductor device shown in FIG. 1.

FIG. 14 is a schematic view of a vehicle equipped with the semiconductor device shown in FIG. 1.

FIG. 15 is a sectional view of a semiconductor device according to a second embodiment of the present disclosure and corresponds to FIG. 7.

FIG. 16 is a sectional view of the semiconductor device shown in FIG. 15 and corresponds to FIG. 8.

FIG. 17 is a partial enlarged view of FIG. 16.

FIG. 18 is a sectional view of a semiconductor device according to a third embodiment of the present disclosure and corresponds to FIG. 7.

FIG. 19 is a sectional view of the semiconductor device shown in FIG. 18 and corresponds to FIG. 8.

FIG. 20 is a partial enlarged view of FIG. 18.

FIG. 21 is a sectional view of a semiconductor device according to a fourth embodiment of the present disclosure and corresponds to FIG. 7.

FIG. 22 is a sectional view of the semiconductor device shown in FIG. 21 and corresponds to FIG. 8.

FIG. 23 is a partial enlarged view of FIG. 22.

FIG. 24 is a plan view of a semiconductor device according to a fifth embodiment of the present disclosure and corresponds to FIG. 3.

FIG. 25 is a plan view of the semiconductor device shown in FIG. 24 and corresponds to FIG. 5.

FIG. 26 is a sectional view taken along line XXVI-XXVI in FIG. 24.

FIG. 27 is a plan view of a semiconductor device according to a sixth embodiment of the present disclosure and corresponds to FIG. 3.

FIG. 28 is a plan view of the semiconductor device shown in FIG. 27 and corresponds to FIG. 5.

FIG. 29 is a sectional view taken along line XXIX-XXIX in FIG. 27.

FIG. 30 is a plan view of a semiconductor device according to a seventh embodiment of the present disclosure.

FIG. 31 is a bottom view of the semiconductor device shown in FIG. 30.

FIG. 32 is a sectional view taken along line XXXII-XXXII in FIG. 30.

FIG. 33 is a sectional view taken along line XXXIII-XXXIII in FIG. 30.

FIG. 34 is a plan view of a semiconductor device according to an eighth embodiment of the present disclosure.

FIG. 35 is a plan view of the semiconductor device shown in FIG. 34 and corresponds to FIG. 2.

FIG. 36 is a plan view of the semiconductor device shown in FIG. 34 and corresponds to FIG. 3.

FIG. 37 is a plan view of the semiconductor device shown in FIG. 34 and corresponds to FIG. 5.

FIG. 38 is a sectional view taken along line XXXVIII-XXXVIII in FIG. 35.

FIG. 39 is a sectional view taken along line XXXIX-XXXIX in FIG. 35.

### DETAILED DESCRIPTION OF EMBODIMENTS

Details of the present disclosure will be explained based on the accompanying drawings.

### First Embodiment

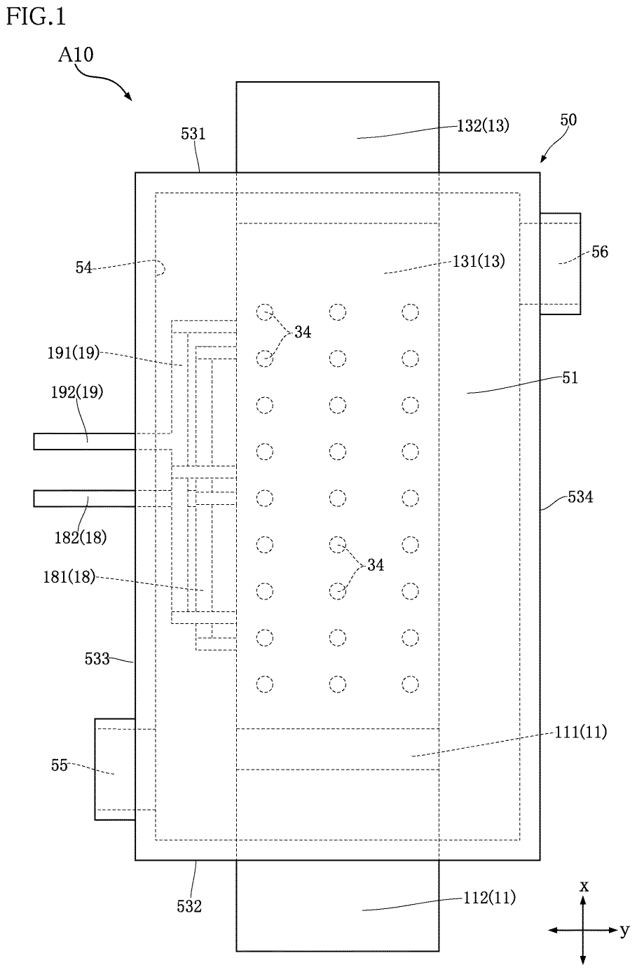

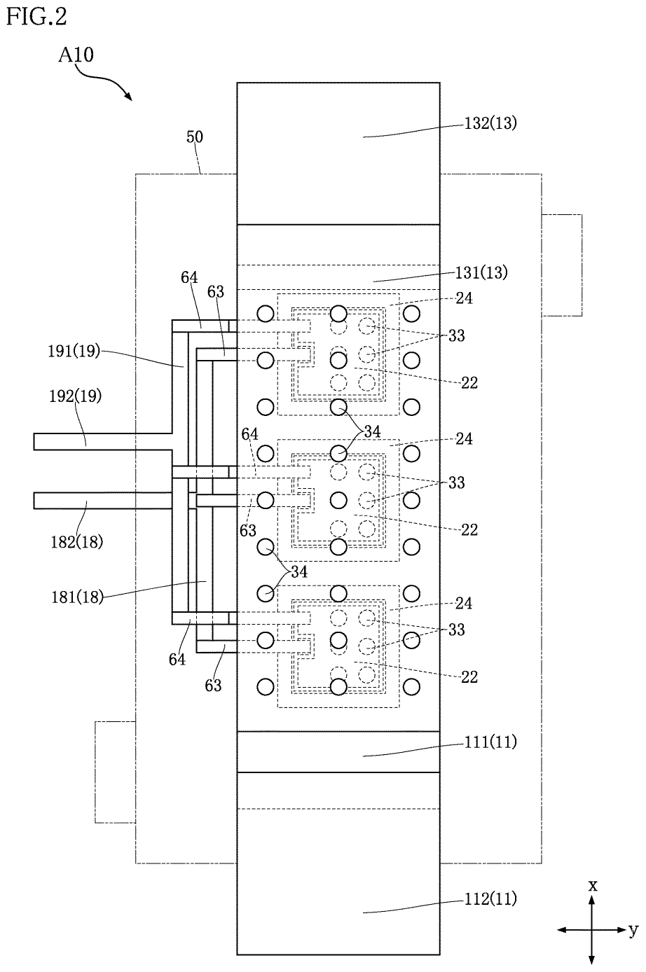

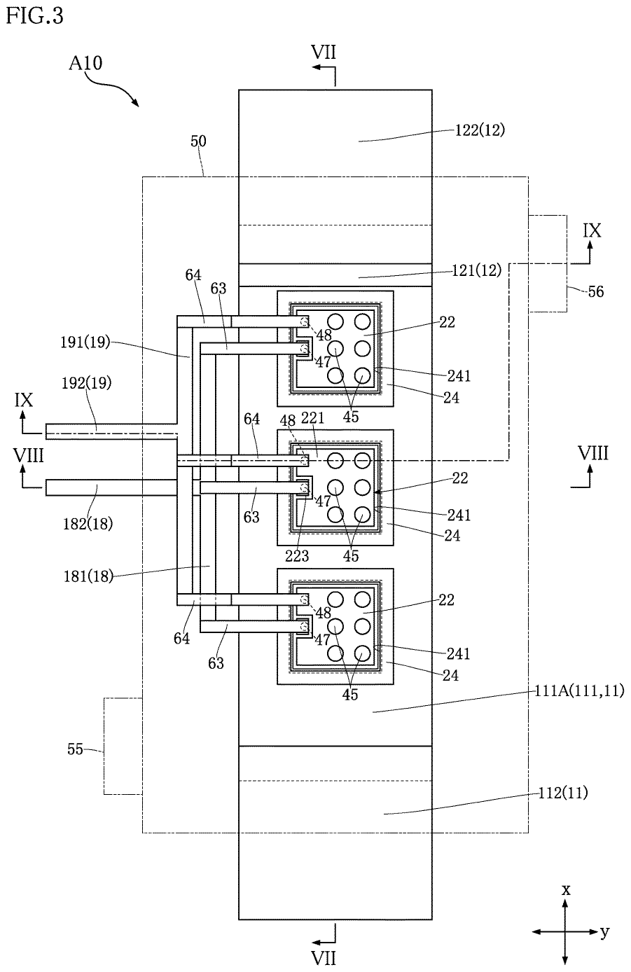

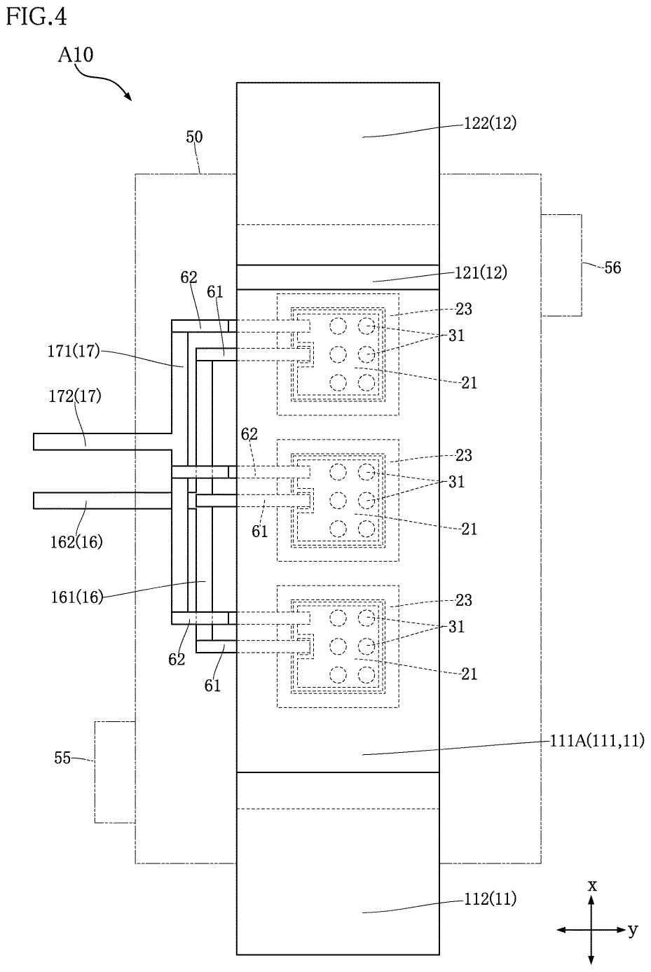

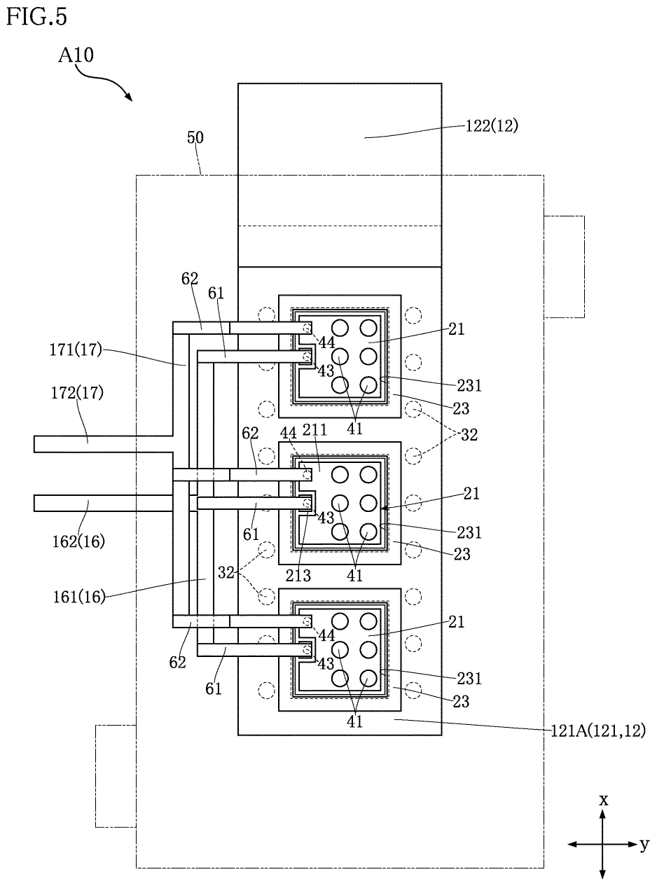

A semiconductor device A10 according to a first embodiment of the present disclosure will be described based on FIGS. 1 to 13. Generally, the semiconductor device A10 is used in a power conversion circuit, such as an inverter. The semiconductor device A10 includes a first terminal 11, a second terminal 12, a third terminal 13, a plurality of first semiconductor elements 21, a plurality of second semiconductor elements 22, a plurality of first protective layers 23, a plurality of second protective layers 24, a plurality of first heat dissipation members 31, a plurality of second heat dissipation members 32, a plurality of third heat dissipation members 33, a plurality of fourth heat dissipation members 34, and a housing 50. The semiconductor device A10 includes a plurality of first pillars 41, a plurality of second pillars 42, a plurality of first gate pillars 43, a plurality of first detection pillars 44, a plurality of third pillars 45, a plurality of fourth pillars 46, a plurality of second gate pillars 47, and a plurality of second detection pillars 48. The semiconductor device A10 further includes a first signal terminal 16, a second signal terminal 17, a third signal terminal 18, a fourth signal terminal 19, a plurality of first leads 61, a plurality of second leads 62, a plurality of third leads 63, and a plurality of fourth leads 64. For ease of understanding, FIGS. 2 to 5 are illustrated as seen through the housing 50. In FIGS. 2 to 5, the housing 50 is indicated by imaginary lines (two-dot chain lines). For ease of understanding, FIG. 3 omits the illustration of the third terminal 13, the second heat dissipation members 32, and the fourth heat dissipation members 34 as compared with FIG. 2. For ease of understanding, FIG. 4 omits the illustration of the third signal terminal 18, the fourth signal terminal 19, the second semiconductor elements 22, the second protective layers 24, the third pillars 45, the fourth pillars 46, the second gate pillars 47, the second detection pillars 48, the third leads 63, and the fourth leads 64 as compared with FIG. 3. For ease of understanding, FIG. 5 omits the illustration of the first terminal 11 and the first heat dissipation members 31 as compared with FIG. 4.

For convenience, in the description of the semiconductor device A10, for example, the direction normal to the first mounting surface 121A of the second terminal 12, described later, is referred to as the “first direction z”. Further, for example, a direction orthogonal to the first direction z is referred to as the “second direction x”. Further, for example, the direction orthogonal to each of the first direction z and the second direction x is referred to as the “third direction y”.

In the semiconductor device A10, a half-bridge circuit including the first semiconductor elements 21 and the second semiconductor elements 22 is formed. The semiconductor device A10 converts the DC power supplied to the second terminal 12 and the third terminal 13 into an AC power by the first semiconductor elements 21 and the second semiconductor elements 22. The second terminal 12 is a P terminal (positive electrode). The third terminal 13 is an N terminal (negative electrode). The converted AC power is inputted to a power supply target, such as a motor, through the first terminal 11.

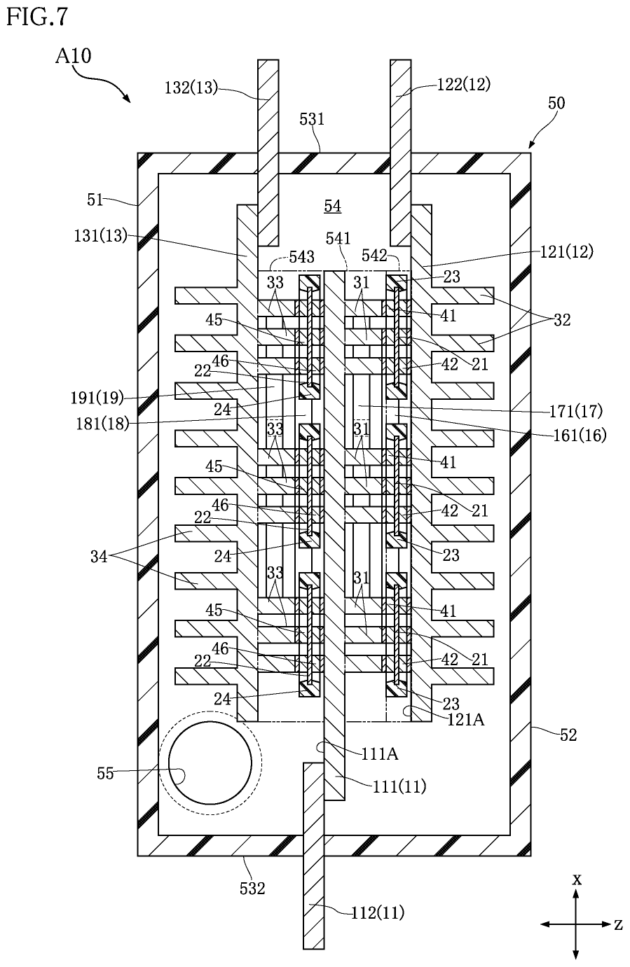

As shown in FIGS. 7 to 9, the housing 50 supports the first terminal 11, the second terminal 12, the third terminal 13, the first signal terminal 16, the second signal terminal 17, the third signal terminal 18, and the fourth signal terminal 19. The housing 50 is made of an insulating material containing resin. Alternatively, the housing 50 may be made of a conductive material containing a metal, such as aluminum (Al).

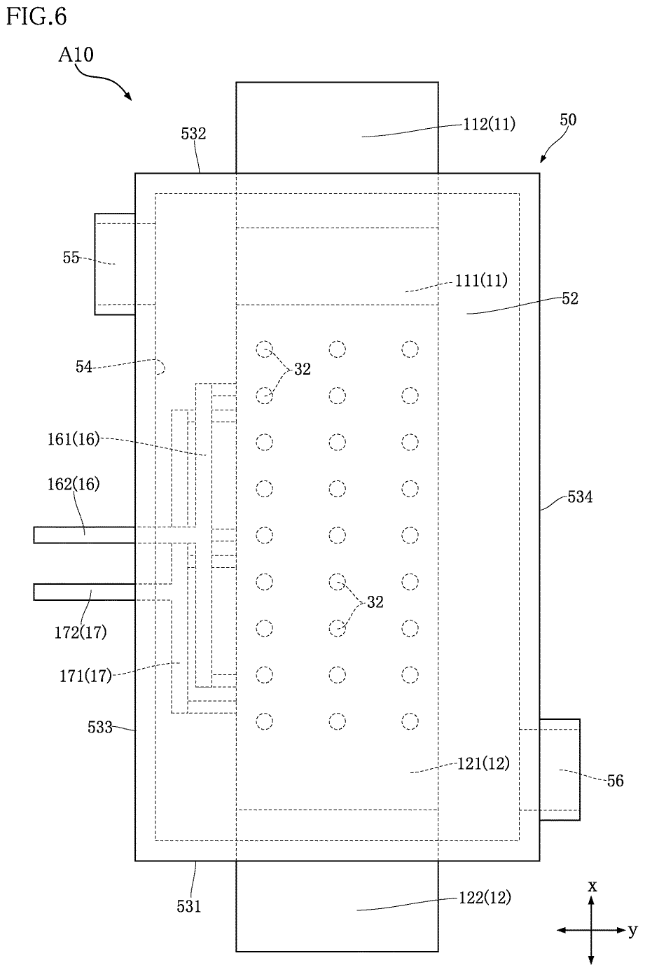

As shown in FIGS. 1 and 6, the housing 50 has a top surface 51, a bottom surface 52, a first side surface 531, a second side surface 532, a third side surface 533, and a fourth side surface 534. The top surface 51 faces one side in the first direction z. The bottom surface 52 faces away from the top surface 51 in the first direction z. The first side surface 531 and the second side surface 532 face away from each other in the second direction x. The third side surface 533 and the fourth side surface 534 face away from each other in the third direction y.

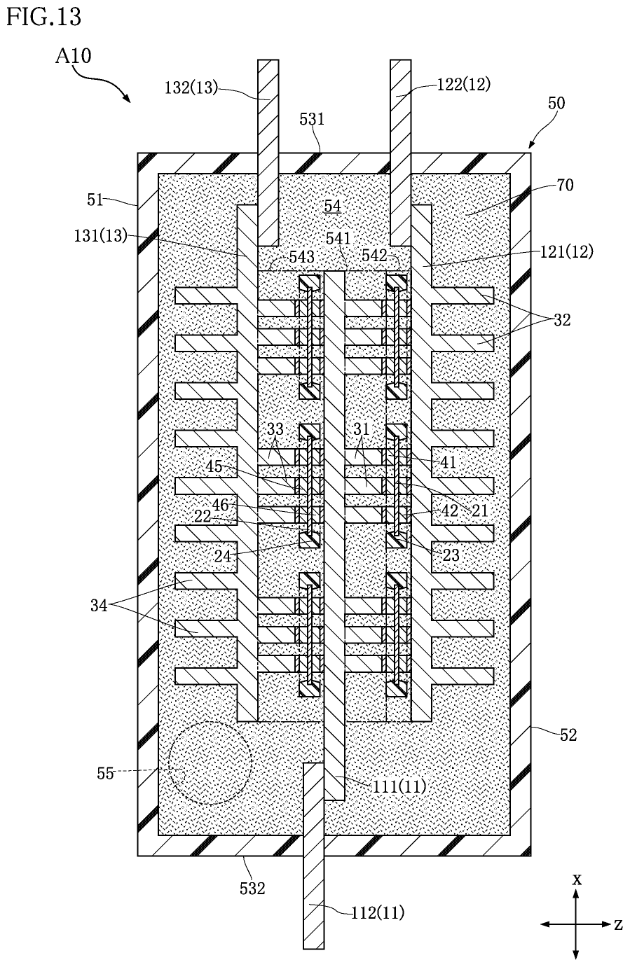

As shown in FIGS. 7 to 9, the housing 50 includes a hollow portion 54. Air flows into the hollow portion 54. Alternatively, as shown in FIG. 13, the hollow portion 54 may be configured to be constantly filled with coolant 70. The hollow portion 54 includes a first flow path 541, a second flow path 542, and a third flow path 543. The first flow path 541 is provided between the first semiconductor elements 21 and the first terminal 11 in the first direction z. The second flow path 542 is provided between the second terminal 12 and the first flow path 541 in the first direction z. The second flow path 542 is connected to the first flow path 541. The third flow path 543 is provided between the first terminal 11 and the third terminal 13 in the first direction z. Here, the coolant 70 shown in FIG. 13 is required to be an insulator. In the present disclosure, the composition of the coolant 70 is not limited as long as the coolant 70 is an insulator.

As shown in FIGS. 1, 3, 4, and 6, the housing 50 has an inlet 55 and an outlet 56. The inlet 55 is open at the third side surface 533 and communicates with the hollow portion 54. The outlet 56 is open at the fourth side surface 534 and communicates with the hollow portion 54. In the housing 50, the coolant 70 shown in FIG. 13 flows into the hollow portion 54 from the inlet 55. The coolant 70 flowing into the hollow portion 54 is discharged through the outlet 56. As shown in FIG. 4, the inlet 55 and the outlet 56 are located on opposite sides of each other with respect to the first heat dissipation members 31 in the second direction x.

The first terminal 11 is located on one side of the first semiconductor elements 21 in the first direction z, as shown in FIGS. 7 to 9. The first terminal 11 is, for example, a metal plate containing copper (Cu). The first terminal 11 has a first base portion 111 and a first extension portion 112. The first base portion 111 is housed in the hollow portion 54 of the housing 50 and in contact with the first flow path 541 and the third flow path 543. The first base portion 111 is in the form of a strip extending in the second direction x. The first base portion 111 has a second mounting surface 111A facing the same side as the top surface 51 of the housing 50 in the first direction z. The first extension portion 112 is conductively bonded to one side of the first base portion 111 in the second direction x. The first extension portion 112 is supported by the housing 50. A part of the first extension portion 112 protrudes outward from the second side surface 532 of the housing 50.

As shown in FIGS. 7 to 9, the second terminal 12 is located opposite the first terminal 11 with respect to the first semiconductor elements 21 in the first direction z. The second terminal 12 is, for example, a metal plate containing copper (Cu). The second terminal 12 has a second base portion 121 and a second extension portion 122. The second base portion 121 is housed in the hollow portion 54 of the housing 50 and in contact with the second flow path 542. The second base portion 121 is in the form of a strip extending in the second direction x. The second base portion 121 has a first mounting surface 121A facing the same side as the top surface 51 of the housing 50 in the first direction z. The second extension portion 122 is conductively bonded to one side of the second base portion 121 in the second direction x. The second extension portion 122 is supported by the housing 50. A part of the second extension portion 122 protrudes outward from the first side surface 531 of the housing 50.

As shown in FIGS. 7 to 9, the third terminal 13 is located opposite the first terminal 11 with respect to the second semiconductor elements 22 in the first direction z. The third terminal 13 is, for example, a metal plate containing copper. The third terminal 13 has a third base portion 131 and a third extension portion 132. The third base portion 131 is housed in the hollow portion 54 of the housing 50 and in contact with third flow path 543. The third base portion 131 is in the form of a strip extending in the second direction x. The third extension portion 132 is conductively bonded to one side of the third base portion 131 in the second direction x. The third extension portion 132 is supported by the housing 50. A part of the third extension portion 132 protrudes outward from the first side surface 531 of the housing 50.

As shown in FIGS. 7 to 9, the first semiconductor elements 21 are located between the first base portion 111 of the first terminal 11 and the second base portion 121 of the second terminal 12 in the first direction z. The first semiconductor elements 21 are housed in the second flow path 542 of the hollow portion 54 of the housing 50. The first semiconductor elements 21 are identical elements. The first semiconductor elements 21 are, for example, MOSFETs (Metal-Oxide-Semiconductor Field-Effect Transistors). Alternatively, the first semiconductor elements 21 may be field-effect transistors including MISFETs (Metal-Insulator-Semiconductor Field-Effect Transistors) or bipolar transistors such as IGBTs (Insulated Gate Bipolar Transistors). In the description of the semiconductor device A10, the first semiconductor elements 21 are described as n-channel type vertical-structure MOSFETs. The first semiconductor elements 21 include a compound semiconductor substrate. The composition of the compound semiconductor substrate includes silicon carbide (SiC). The first semiconductor elements 21 are arranged along the second direction x.

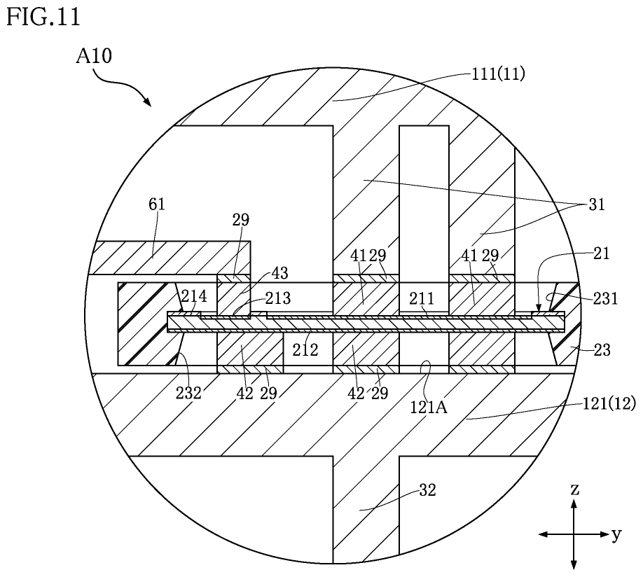

As shown in FIG. 11, each of the first semiconductor elements 21 has a first electrode 211, a second electrode 212, a first gate electrode 213, and a first protective film 214.

As shown in FIG. 11, the first electrode 211 faces the first base portion 111 of the first terminal 11. The first electrode 211 electrically conducts to the first terminal 11. A current corresponding to the power converted by the first semiconductor element 21 flows through the first electrode 211. That is, the first electrode 211 corresponds to the source of the first semiconductor element 21. The first electrode 211 is in contact with the first flow path 541 of the hollow portion 54 of the housing 50.

As shown in FIG. 11, the second electrode 212 faces the first mounting surface 121A of the second base portion 121 of the second terminal 12. The second electrode 212 electrically conducts to the second terminal 12. A current corresponding to the power before conversion by the first semiconductor element 21 flows through the second electrode 212. That is, the second electrode 212 corresponds to the drain of the first semiconductor element 21.

As shown in FIG. 11, the first gate electrode 213 is located on the same side as the first electrode 211 in the first direction z. A gate voltage for driving the first semiconductor element 21 is applied to the first gate electrode 213. As shown in FIG. 5, as viewed in the first direction z, the area of the first gate electrode 213 is smaller than the area of the first electrode 211.

As shown in FIG. 11, the first protective film 214 is located on the same side as the first electrode 211 in the first direction z. As viewed in the first direction z, the first protective film 214 surrounds the peripheries of the first electrode 211 and the first gate electrode 213. The first protective film 214 is an insulator. The first protective film 214 may be formed by laminating, for example, a silicon dioxide (SiO₂) layer, a silicon nitride (Si₃N₄) layer, and a polybenzoxazole (PBO) layer in that order. In the first protective film 214, a polyimide layer may be used instead of the polybenzoxazole layer.

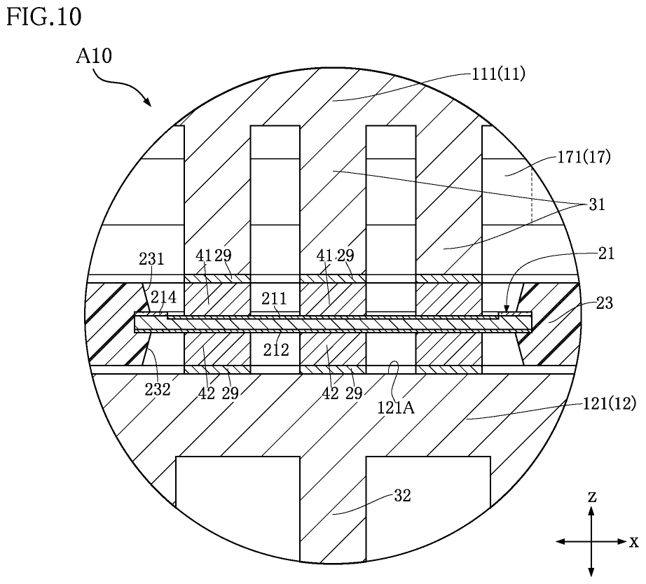

As shown n FIGS. 5 and 7 to 9, each of the first protective layers 23 covers at least a part of one of the first semiconductor elements 21. The first protective layers 23 are insulators. The first protective layers 23 are made of a material containing, for example, epoxy resin. As shown in FIG. 5, as viewed in the first direction z, each of the first protective layers 23 covers the entire periphery of one of the first semiconductor elements 21. As shown in FIGS. 10 and 11, each of the first protective layers 23 covers a part of the first protective film 214 of one of the first semiconductor elements 21.

As shown in FIGS. 10 and 11, each of the first protective layers 23 has a first opening 231 and a second opening 232. The first opening 231 and the second opening 232 are located on opposite sides of each other in the first direction z. From the first opening 231, the first electrode 211 and the first gate electrode 213 of one of the first semiconductor elements 21 are exposed. The first opening 231 is connected to the first flow path 541 of the hollow portion 54 of the housing 50. The size of the cross section of the first opening 231 taken orthogonal to the first direction z increases from the first electrode 211 toward the first heat dissipation members 31. From the second opening 232, the second electrode 212 of one of the first semiconductor elements 21 is exposed. The size of the cross section of the second opening 232 taken orthogonal to the first direction z increases from the second electrode 212 toward the second base portion 121 of the second terminal 12.

As shown in FIGS. 7 to 9, the second semiconductor elements 22 are located opposite the first semiconductor elements 21 with respect to the first terminal 11 in the first direction z. Additionally, the second semiconductor elements 22 are located between the first base portion 111 of the first terminal 11 and the third base portion 131 of the third terminal 13 in the first direction z. The second semiconductor elements 22 are housed in the third flow path 543 of the hollow portion 54 of the housing 50. As viewed in the first direction z, the second semiconductor elements 22 individually overlap with the first semiconductor elements 21. The second semiconductor elements 22 are identical to the first semiconductor elements 21. Thus, the second semiconductor elements 22 are n-channel type vertical-structure MOSFETs. The second semiconductor elements 22 are arranged along the second direction x.

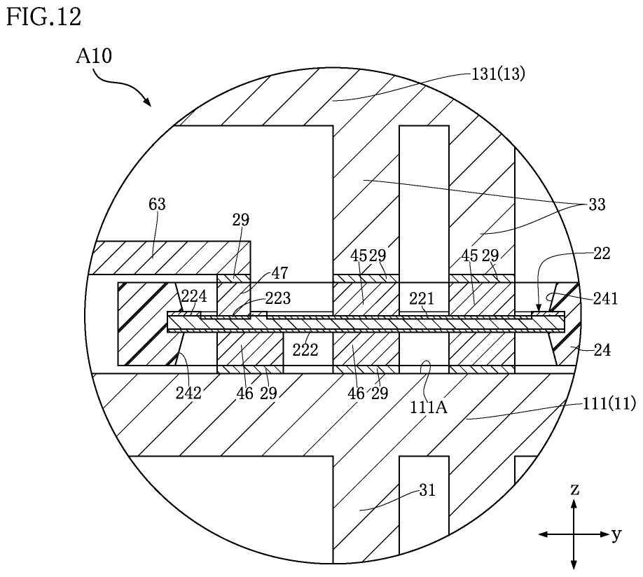

As shown in FIG. 12, each of the second semiconductor elements 22 has a third electrode 221, a fourth electrode 222, a second gate electrode 223, and a second protective film 224.

As shown in FIG. 12, the third electrode 221 faces the third base portion 131 of the third terminal 13. The third electrode 221 electrically conducts to the third terminal 13. A current corresponding to the power converted by the second semiconductor element 22 flows through the third electrode 221. That is, the third electrode 221 corresponds to the source of the second semiconductor element 22. The third electrode 221 is in contact with the third flow path 543 of the hollow portion 54 of the housing 50.

As shown in FIG. 12, the fourth electrode 222 faces the second mounting surface 111A of the first base portion 111 of the first terminal 11. The fourth electrode 222 electrically conducts to the first terminal 11. A current corresponding to the power before conversion by the second semiconductor element 22 flows through the fourth electrode 222. That is, the fourth electrode 222 corresponds to the drain of the second semiconductor element 22.

As shown in FIG. 12, the second gate electrode 223 is located on the same side as the third electrode 221 in the first direction z. A gate voltage for driving the second semiconductor element 22 is applied to the second gate electrode 223. As shown in FIG. 3, as viewed in the first direction z, the area of the second gate electrode 223 is smaller than the area of the third electrode 221.

As shown in FIG. 12, the second protective film 224 is located on the same side as the third electrode 221 in the first direction z. As viewed in the first direction z, the second protective film 224 surrounds the peripheries of the third electrode 221 and the second gate electrode 223. The second protective film 224 is an insulator. The composition of the second protective film 224 is the same as that of the first protective film 214 of each of the first semiconductor elements 21.

As shown in FIGS. 3 and 7 to 9, each of the second protective layers 24 covers at least a part of one of the second semiconductor elements 22. The second protective layers 24 are insulators. The second protective layers 24 are made of a material containing, for example, epoxy resin. As shown in FIG. 3, as viewed in the first direction z, each of the second protective layers 24 covers the entire periphery of one of the second semiconductor elements 22. As shown in FIG. 12, each of the second protective layers 24 covers a part of the second protective film 224 of one of the second semiconductor elements 22.

As shown in FIG. 12, each of the second protective layers 24 has a third opening 241 and a fourth opening 242. The third opening 241 and the fourth opening 242 are located on opposite sides of each other in the first direction z. From the third opening 241, the third electrode 221 and the second gate electrode 223 of one of the second semiconductor elements 22 are exposed. The third opening 241 is connected to the third flow path 543 of the hollow portion 54 of the housing 50. The size of the cross section of the third opening 241 taken orthogonal to the first direction z increases from the third electrode 221 toward the second heat dissipation members 32. From the fourth opening 242, the fourth electrode 222 of one of the second semiconductor elements 22 is exposed. The size of the cross section of fourth opening 242 taken orthogonal to the first direction z increases from the fourth electrode 222 toward the first base portion 111 of the first terminal 11.

As shown in FIGS. 10 and 11, each of the first pillars 41 is electrically connected to the first electrode 211 of one of the first semiconductor elements 21. The first pillars 41 contain, for example, copper. The first pillars 41 are formed, for example, by plating. The first pillars 41 are housed in the first flow path 541 of the hollow portion 54 of the housing 50. At least a part of each of the first pillars 41 is housed in the first opening 231 of the relevant one of the first protective layers 23. In the semiconductor device A10, each of the first pillars 41 is entirely housed in the relevant first opening 231. The first pillars 41 are spaced apart from each other in a direction orthogonal to the first direction z. The dimension of each of the first pillars 41 in the first direction z is smaller than the dimension of each of the first heat dissipation members 31 in the first direction z.

As shown in FIGS. 10 and 11, each of the second pillars 42 is electrically connected to the second electrode 212 of one of the first semiconductor elements 21. The second pillars 42 contain, for example, copper. The second pillars 42 are formed, for example, by plating. The second pillars 42 are housed in the second flow path 542 of the hollow portion 54 of the housing 50. At least a part of each of the second pillars 42 is housed in the second opening 232 of the relevant one of the first protective layers 23. In the semiconductor device A10, each of the second pillars 42 is entirely housed in the relevant second opening 232. The second pillars 42 are spaced apart from each other in a direction orthogonal to the first direction z. The dimension of each of the second pillars 42 in the first direction z is smaller than the dimension of each of the first heat dissipation members 31 in the first direction z. Each of the second pillars 42 is conductively bonded to the first mounting surface 121A of the second base portion 121 of the second terminal 12 via a bonding layer 29. Thus, the second electrode 212 of each of the first semiconductor elements 21 electrically conducts to the second terminal 12. The bonding layer 29 is solder. Alternatively, the bonding layer 29 may be a sintered metal containing, for example, silver (Ag).

As shown in FIG. 11, the first gate pillars 43 are individually electrically connected to the first gate electrodes 213 of the first semiconductor elements 21. The first gate pillars 43 contain, for example, copper. The first gate pillars 43 are formed, for example, by plating. At least a part of each of the first gate pillars 43 is housed in the first opening 231 of the relevant one of the first protective layers 23.

As shown in FIG. 5, the first detection pillars 44 are individually electrically connected to the first electrodes 211 of the first semiconductor elements 21. The first detection pillars 44 contain, for example, copper. The first detection pillars 44 are formed, for example, by plating. At least a part of each of the first detection pillars 44 is housed in the first opening 231 of the relevant one of the first protective layers 23.

As shown in FIG. 12, each of the third pillars 45 is electrically connected to the third electrode 221 of one of the second semiconductor elements 22. The third pillars 45 contain, for example, copper. The third pillars 45 are formed, for example, by plating. The third pillars 45 are housed in the third flow path 543 of the hollow portion 54 of the housing 50. At least a part of each of the third pillars 45 is housed in the third opening 241 of the relevant one of the second protective layers 24. In the semiconductor device A10, each of the third pillars 45 is entirely housed in the relevant third opening 241. The third pillars 45 are spaced apart from each other in a direction orthogonal to the first direction z. The dimension of each of the third pillars 45 in the first direction z is smaller than the dimension of each of the second heat dissipation members 32 in the first direction z.

As shown in FIG. 12, each of the fourth pillars 46 is electrically connected to the fourth electrode 222 of one of the second semiconductor elements 22. The fourth pillars 46 contain, for example, copper. The fourth pillars 46 are formed, for example, by plating. The fourth pillars 46 are housed in the third flow path 543 of the hollow portion 54 of the housing 50. At least a part of each of the fourth pillars 46 is housed in the fourth opening 242 of the relevant one of the second protective layers 24. In the semiconductor device A10, each of the fourth pillars 46 is entirely housed in the corresponding fourth opening 242. The fourth pillars 46 are spaced apart from each other in a direction orthogonal to the first direction z. The dimension of each of the fourth pillars 46 in the first direction z is smaller than the dimension of each of the second heat dissipation members 32 in the first direction z. Each of the fourth pillars 46 is conductively bonded to the second mounting surface 111A of the first base portion 111 of the first terminal 11 via a bonding layer 29. Thus, the fourth electrode 222 of each of the second semiconductor elements 22 electrically conducts to the first terminal 11.

As shown in FIG. 12, the second gate pillars 47 are individually electrically connected to the second gate electrodes 223 of the second semiconductor elements 22. The second gate pillars 47 contain, for example, copper. The second gate pillars 47 are formed, for example, by plating. At least a part of each of the second gate pillars 47 is housed in the third opening 241 of the relevant one of the second protective layers 24.

As shown in FIG. 3, the second detection pillars 48 are individually electrically connected to the third electrode 221 of the second semiconductor elements 22. The second detection pillars 48 contain, for example, copper. The second detection pillars 48 are formed, for example, by plating. At least a part of each of the second detection pillars 48 is housed in the third opening 241 of the relevant one of the second protective layers 24.

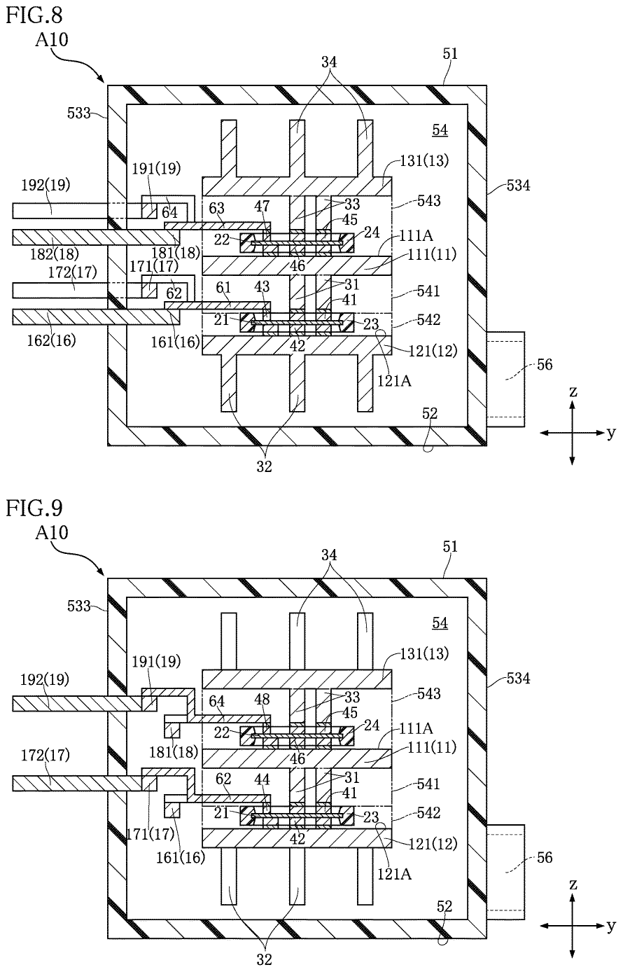

As shown in FIGS. 4 and 5, the first signal terminal 16 is located on one side of the first terminal 11 and the second terminal 12 in the third direction y. The first signal terminal 16 is supported by the housing 50. The first signal terminal 16 electrically conducts to the respective first gate electrodes 213 of the first semiconductor elements 21. A gate voltage for driving the first semiconductor elements 21 is applied to the first signal terminal 16. The first signal terminal 16 is, for example, a metal lead containing copper. The first signal terminal 16 has an inner portion 161 and an outer portion 162. The inner portion 161 is housed in the housing 50. Parts of the inner portion 161 are housed in the hollow portion 54 of the housing 50. The inner portion 161 includes a part extending in the second direction x. The outer portion 162 is connected to the inner portion 161. As shown in FIG. 8, the outer portion 162 protrudes outward from the third side surface 533 of the housing 50.

Each of the first leads 61 electrically conducts to the first gate electrode 213 of one of the first semiconductor elements 21 and the first signal terminal 16. As shown in FIG. 5, each of the first leads 61 extends in the third direction y. As shown in FIG. 8, a part of each of the first leads 61 is housed in the first flow path 541 of the hollow portion 54 of the housing 50. The first leads 61 are, for example, metal leads containing copper. As shown in FIG. 11, one end of each of the first leads 61 in the third direction y is conductively bonded to one of the first gate pillars 43 via a bonding layer 29. The other end of each of the first leads 61 in the third direction y is conductively bonded to the inner portion 161 of the first signal terminal 16.

As shown in FIGS. 4 and 5, the second signal terminal 17 is located on the same side as the first signal terminal 16 with respect to the first terminal 11 and the second terminal 12 in the third direction y. The second signal terminal 17 is supported by the housing 50. The second signal terminal 17 electrically conducts to the respective first electrodes 211 of the first semiconductor elements 21. A voltage having the same potential as the voltage applied to the respective first electrodes 211 of the first semiconductor elements 21 is applied to the second signal terminal 17. The second signal terminal 17 is, for example, a metal lead containing copper. The second signal terminal 17 has an inner portion 171 and an outer portion 172. The inner portion 171 is housed in the housing 50. Parts of the inner portion 171 are housed in the hollow portion 54 of the housing 50. The inner portion 171 includes a part extending in the second direction x. As shown in FIGS. 8 and 9, the inner portion 171 is located closer to the top surface 51 of the housing 50 than is the inner portion 161 of the first signal terminal 16. The outer portion 172 is connected to the inner portion 171. As shown in FIG. 9, the outer portion 172 protrudes outward from the third side surface 533 of the housing 50.

Each of the second leads 62 electrically conducts to the first electrode 211 of one of the first semiconductor elements 21 and the second signal terminal 17. As shown in FIG. 5, each of the second leads 62 extends in the third direction y as viewed in the first direction z. As shown in FIG. 9, each of the second leads 62 extends over the inner portion 161 of the first signal terminal 16. A part of each of the second leads 62 is housed in the first flow path 541 of the hollow portion 54 of the housing 50. The second leads 62 are, for example, metal leads containing copper. One end of each of the second leads 62 in the third direction y is conductively bonded to one of the first detection pillars 44. The other end of each of the second leads 62 in the third direction y is conductively bonded to the inner portion 171 of the second signal terminal 17.

As shown in FIGS. 2 and 3, the third signal terminal 18 is located on one side of the first terminal 11 and the third terminal 13 in the third direction y. As viewed in the first direction z, the third signal terminal 18 overlaps with the first signal terminal 16. The third signal terminal 18 is supported by the housing 50. The third signal terminal 18 electrically conducts to the respective second gate electrodes 223 of the second semiconductor elements 22. A gate voltage for driving the second semiconductor elements 22 is applied to the third signal terminal 18. The third signal terminal 18 is, for example, a metal lead containing copper. The third signal terminal 18 has an inner portion 181 and an outer portion 182. The inner portion 181 is housed in the housing 50. Parts of the inner portion 181 are housed in the hollow portion 54 of the housing 50. The inner portion 181 includes a part extending in the second direction x. The outer portion 182 is connected to the inner portion 181. As shown in FIG. 8, the outer portion 182 protrudes outward from the third side surface 533 of the housing 50.

Each of the third leads 63 electrically conducts to the second gate electrode 223 of one of the second semiconductor elements 22 and the third signal terminal 18. As shown in FIG. 3, each of the third leads 63 extends in the third direction y. As shown in FIG. 8, a part of each of the third leads 63 is housed in the third flow path 543 of the hollow portion 54 of the housing 50. The third leads 63 are, for example, metal leads containing copper. As shown in FIG. 12, one end of each of the third leads 63 in the third direction y is conductively bonded to one of the second gate pillars 47 via a bonding layer 29. The other end of each of the third leads 63 in the third direction y is conductively bonded to the inner portion 181 of the third signal terminal 18.

As shown in FIGS. 2 and 3, the fourth signal terminal 19 is located on the same side as the third signal terminal 18 with respect to the first terminal 11 and the third terminal 13 in the third direction y. As viewed in the first direction z, the fourth signal terminal 19 overlaps with the second signal terminal 17. The fourth signal terminal 19 is supported by the housing 50. The fourth signal terminal 19 electrically conducts to the respective third electrodes 221 of the second semiconductor elements 22. A voltage having the same potential as the voltage applied to the respective third electrodes 221 of the second semiconductor elements 22 is applied to the fourth signal terminal 19. The fourth signal terminal 19 is, for example, a metal lead containing copper. The fourth signal terminal 19 has an inner portion 191 and an outer portion 192. The inner portion 191 is housed in the housing 50. Parts of the inner portion 191 are housed in the hollow portion 54 of the housing 50. The inner portion 191 includes a part extending in the second direction x. As shown in FIGS. 8 and 9, the inner portion 191 is located closer to the top surface 51 of the housing 50 than is the inner portion 181 of the third signal terminal 18. The outer portion 192 is connected to the inner portion 191. As shown in FIG. 9, the outer portion 192 protrudes outward from the third side surface 533 of the housing 50.

Each of the fourth leads 64 electrically conducts to the third electrode 221 of one of the second semiconductor elements 22 and the fourth signal terminal 19. As shown in FIG. 3, each of the fourth leads 64 extends in the third direction y as viewed in the first direction z. As shown in FIG. 9, each of the fourth leads 64 extends over the inner portion 181 of the third signal terminal 18. A part of each of the fourth leads 64 is housed in the third flow path 543 of the hollow portion 54 of the housing 50. The fourth leads 64 are, for example, metal leads containing copper. One end of each of the fourth leads 64 in the third direction y is conductively bonded to one of the second detection pillars 48. The other end of each of the fourth leads 64 in the third direction y is conductively bonded to the inner portion 191 of the fourth signal terminal 19.

As shown in FIGS. 7 to 9, the first heat dissipation members 31 are electrically connected to the first base portion 111 of the first terminal 11. The first heat dissipation members 31 are housed in the first flow path 541 of the hollow portion 54 of the housing 50. The first heat dissipation members 31 are, for example, rod members containing copper. The first heat dissipation members 31 extend in the first direction z. In the semiconductor device A10, one end of each of the first heat dissipation members 31 in the first direction z is conductively bonded to the first base portion 111 by, for example, laser welding. As shown in FIGS. 10 and 11, the other ends in the first direction z of the first heat dissipation members 31 are individually conductively bonded to the first pillars 41 via bonding layers 29. Thus, the first electrode 211 of each of the first semiconductor elements 21 electrically conducts to the first terminal 11.

As shown in FIGS. 7 and 8, the second heat dissipation members 32 are electrically connected to the second base portion 121 of the second terminal 12. The second heat dissipation members 32 are located opposite the first semiconductor elements 21 with respect to the second terminal 12 in the first direction z. The second heat dissipation members 32 are housed in the hollow portion 54 of the housing 50. The second heat dissipation members 32 are, for example, rod members containing copper. The second heat dissipation members 32 extend in the first direction z. In the semiconductor device A10, one end in the first direction z of each of the second heat dissipation members 32 is conductively bonded to the second base portion 121 by, for example, laser welding.

As shown in FIGS. 7 to 9, the third head dissipation members 33 are electrically connected to the third base portion 131 of the third terminal 13. The third head dissipation members 33 are housed in the third flow path 543 of the hollow portion 54 of the housing 50. The third head dissipation members 33 are, for example, rod members containing copper. The third head dissipation members 33 extend in the first direction z. In the semiconductor device A10, one end of each of the third head dissipation members 33 in the first direction z is conductively bonded to the first base portion 111 by, for example, laser welding. As shown in FIG. 12, the other ends of the third head dissipation members 33 in the first direction z are individually conductively bonded to the third pillars 45 via bonding layers 29. Thus, the third electrode 221 of each of the second semiconductor elements 22 electrically conducts to the third terminal 13.

As shown in FIGS. 7 and 8, the fourth heat dissipation members 34 are electrically connected to the third base portion 131 of the third terminal 13. The fourth heat dissipation members 34 are located opposite the second semiconductor elements 22 with respect to the third terminal 13 in the first direction z. The fourth heat dissipation members 34 are housed in the hollow portion 54 of the housing 50. The fourth heat dissipation members 34 are, for example, rod members containing copper. The fourth heat dissipation members 34 extend in the first direction z. In the semiconductor device A10, one end of each of the fourth heat dissipation members 34 in the first direction z is conductively bonded to the third base portion 131 by, for example, laser welding.

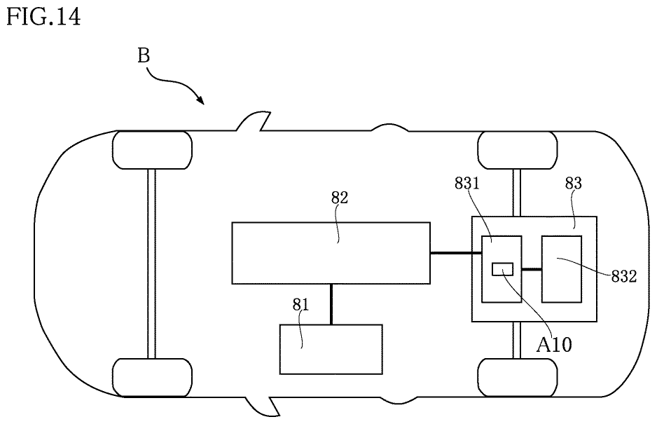

Next, a vehicle B equipped with the semiconductor device A10 will be described based on FIG. 14. The vehicle B may be, for example, an electric vehicle (EV).

As shown in FIG. 14, the vehicle B includes an on-board charger 81, a storage battery 82, and a drive system 83. The on-board charger 81 receives electric power wirelessly from a power supply facility (not shown) installed outdoors. Alternatively, power supply from the power supply facility to the on-board charger 81 may performed via a wired connection. The on-board charger 81 includes a step-up DC-DC converter. The voltage of the power supplied to the on-board charger 81 is increased by the converter and then supplied to the storage battery 82. The increased voltage is, for example, 600 V.

The drive system 83 drives the vehicle B. The drive system 83 has an inverter 831 and a driving source 832. The semiconductor device A10 constitutes a part of the inverter 831. The power stored in the storage battery 82 is supplied to the inverter 831. The power supplied from the storage battery 82 to the inverter 831 is a DC power. Unlike the power system shown in FIG. 14, a step-up DC-DC converter may be additionally provided between the storage battery 82 and the inverter 831. The inverter 831 converts DC power into AC power. The inverter 831 including the semiconductor device A10 electrically conducts to the driving source 832. The driving source 832 has an AC motor and a transmission. When the AC power converted by the inverter 831 is supplied to the driving source 832, the AC motor rotates, and the rotation is transmitted to the transmission. The transmission appropriately reduces the rotation speed transmitted from the AC motor and rotates the drive shaft of the vehicle B. Thus, the vehicle B is driven. When driving the vehicle B, it is necessary to freely control the rotation speed of the AC motor based on the information such as the amount of movement of the accelerator pedal. The semiconductor device A10 in the inverter 831 is necessary to output the AC power with a frequency corresponding to the required rotation speed of the AC motor.

Next, the effects of the semiconductor device A10 will be described.

The semiconductor device A10 includes the first semiconductor elements 21, the first terminal 11, the first pillars 41, and the first heat dissipation members 31. The first pillars 41 are electrically connected to the first electrodes 211 of the first semiconductor elements 21. The first heat dissipation members 31 are electrically connected to the first terminal 11. In the first direction z, the first flow path 541 is provided between the first semiconductor elements 21 and the first terminal 11. The first pillars 41 and the first heat dissipation members 31 are housed in the first flow path 541. The first heat dissipation members 31 are conductively bonded to the first pillars 41. With such a configuration, as shown in FIG. 13, when the coolant 70 is introduced into the hollow portion 54 of the housing 50, the coolant 70 flows down into the first flow path 541. As a result, the coolant 70 comes into direct contact with at least the first heat dissipation members 31, which improves the cooling efficiency of the semiconductor device A10 compared to conventional configurations. Thus, with the present configuration, the semiconductor device A10 is capable of improving cooling efficiency.

The semiconductor device A10 further includes first protective layers 23 that are insulators. Each of the first protective layers 23 covers at least a part of a first semiconductor element 21. With such a configuration, the first semiconductor element 21 can be protected against external factors. In this case, from the viewpoint of protecting the first semiconductor element 21, it is preferable that the first protective layer 23 covers the entire periphery of the first semiconductor element 21 as viewed in the first direction z. Furthermore, by configuring the first protective layer 23 to cover a part of the first protective film 214, leakage current from the first semiconductor element 21 can be effectively suppressed.

The first protective layer 23 has the first opening 231 through which the first electrode 211 of the first semiconductor element 21 is exposed. At least a part of the first pillar 41 is housed in the first opening 231. With such a configuration, it is possible to suppress the application of external forces in a direction orthogonal to the first direction z to the first pillar 41, particularly during the manufacturing of the semiconductor device A10.

The first terminal 11 is in contact with the first flow path 541. With such a configuration, the coolant 70 comes into direct contact with the first terminal 11 as well, which further improves the cooling efficiency of the semiconductor device A10.

The first electrode 211 of each first semiconductor element 21 is in contact with the first flow path 541. With such a configuration, the coolant 70 comes into direct contact with the first electrode 211 as well, which further improves the cooling efficiency of the semiconductor device A10. In this case, the size of the cross section of first opening 231 of the first protective layer 23 taken orthogonal to the first direction z increases from the first electrode 211 toward the first heat dissipation members 31. With such a configuration, the coolant 70 flows more readily into the first opening 231, thereby more readily coming into direct contact with the first pillar 41 in addition to the first electrode 211.

The semiconductor device A10 further includes the second terminal 12. The first semiconductor elements 21 electrically conducts to the second terminal 12. In the first direction z, the second flow path 542 connected to the first flow path 541 is provided between the second terminal 12 and the first flow path 541. The second terminal 12 is in contact with the second flow path 542. With such a configuration, the coolant 70 comes into direct contact with the second terminal 12 as well, which further improves the cooling efficiency of the semiconductor device A10.

The semiconductor device A10 further includes the housing 50 that supports the first terminal 11, the second terminal 12, and the third terminal 13. The housing 50 has the inlet 55 and the outlet 56. The inlet 55 and the outlet 56 are located on opposite sides of each other with respect to the first heat dissipation members 31 in a direction orthogonal to the first direction z. Such a configuration allows the coolant 70 to flow down in such a manner that the coolant 70 readily comes into direct contact with the first heat dissipation members 31.

### Second Embodiment

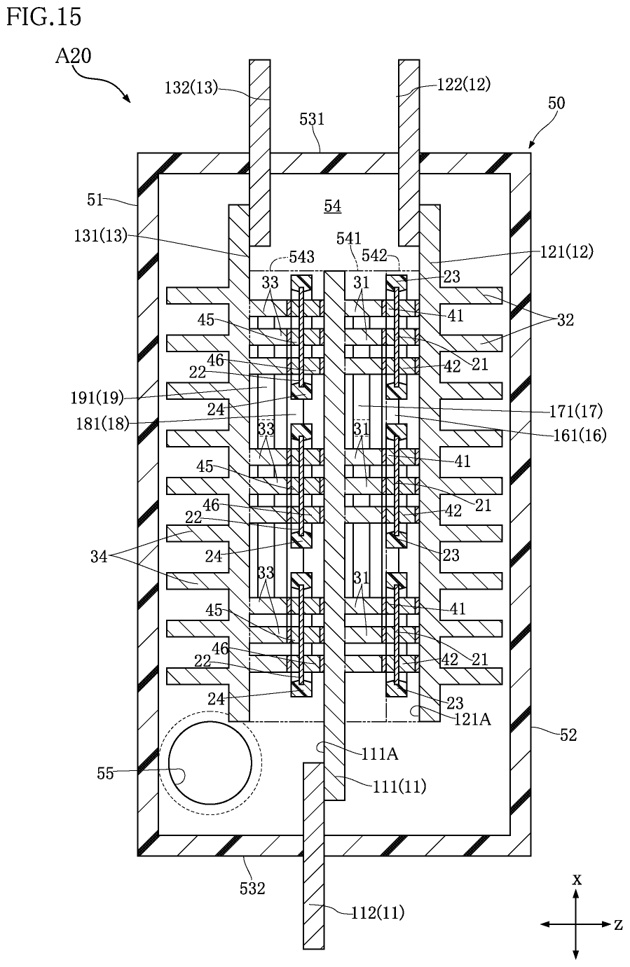

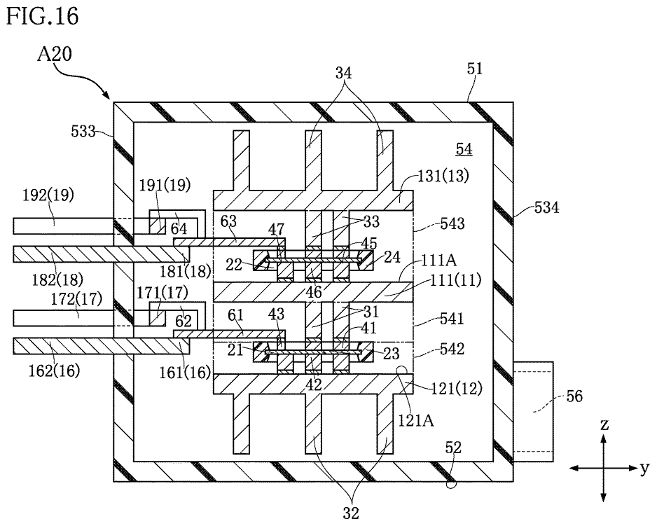

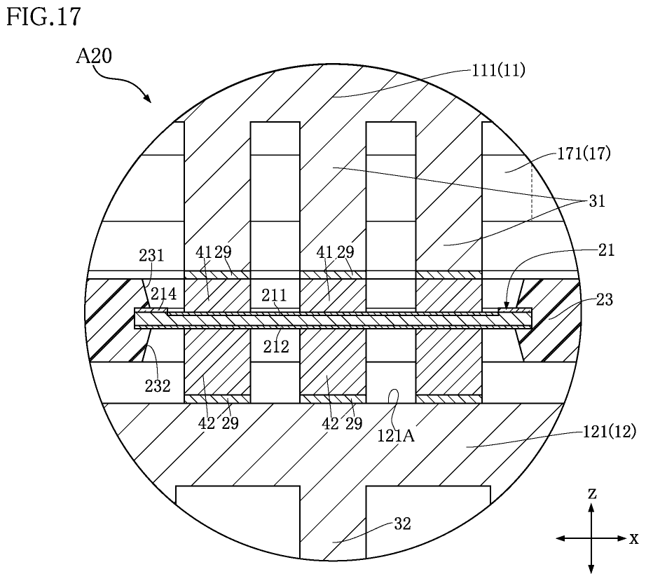

A semiconductor device A20 according to a second embodiment of the present disclosure will be described based on FIGS. 15 to 17. In these figures, the elements that are identical or similar to those of the semiconductor device A10 described above are denoted by the same reference signs, and the descriptions thereof are omitted. FIG. 15 corresponds to FIG. 7, which shows the semiconductor device A10. FIG. 16 corresponds to FIG. 8, which shows the semiconductor device A10.

The semiconductor device A20 differs from the semiconductor device A10 in the configurations of the first protective layers 23, the second protective layers 24, the second pillars 42, and the fourth pillars 46.

As shown in FIGS. 15 to 17, each of the second pillars 42 includes a part protruding in the first direction z from the second opening 232 of one of the first protective layers 23. Each of the first protective layers 23 is spaced apart from the second base portion 121 of the second terminal 12. Thus, a part of the second flow path 542 of the hollow portion 54 of the housing 50 is located between the first mounting surface 121A of the second base portion 121 and the first protective layers 23. Thus, the second opening 232 of each of the first protective layers 23 is connected to the second flow path 542. The second electrode 212 of each first semiconductor element 21 is in contact with the second flow path 542.

As shown in FIGS. 15 and 16, each of the fourth pillars 46 includes a part protruding in the first direction z from the fourth opening 242 of one of the second protective layers 24. Each of the second protective layers 24 is spaced apart from the first base portion 111 of the first terminal 11. Thus, a part of the third flow path 543 of the hollow portion 54 of the housing 50 is located between the second mounting surface 111A of the first base portion 111 and the second protective layers 24. Thus, the fourth opening 242 of each of the second protective layers 24 is connected to the third flow path 543. The fourth electrode 222 of each second semiconductor element 22 is in contact with the third flow path 543.

Next, the effects of the semiconductor device A20 will be described.

The semiconductor device A20 includes the first semiconductor elements 21, the first terminal 11, the first pillars 41, and the first heat dissipation members 31. The first pillars 41 are electrically connected to the first electrodes 211 of the first semiconductor elements 21. The first heat dissipation members 31 are electrically connected to the first terminal 11. In the first direction z, the first flow path 541 is provided between the first semiconductor elements 21 and the first terminal 11. The first pillars 41 and the first heat dissipation members 31 are housed in the first flow path 541. The first heat dissipation members 31 are conductively bonded to the first pillars 41. Therefore, with the present configuration, the semiconductor device A10 is also capable of improving cooling efficiency. Furthermore, the semiconductor device A20 has a configuration in common with the semiconductor device A10, thereby achieving the same effect as the semiconductor device A10.

In the semiconductor device A20, a part of the second flow path 542 is located between the second terminal 12 and the first protective layers 23 in the first direction z. The second electrode 212 of each first semiconductor element 21 is in contact with the second flow path 542. With such a configuration, the coolant 70 comes into direct contact with the second electrode 212 as well, which further improves the cooling efficiency of the semiconductor device A20.

### Third Embodiment

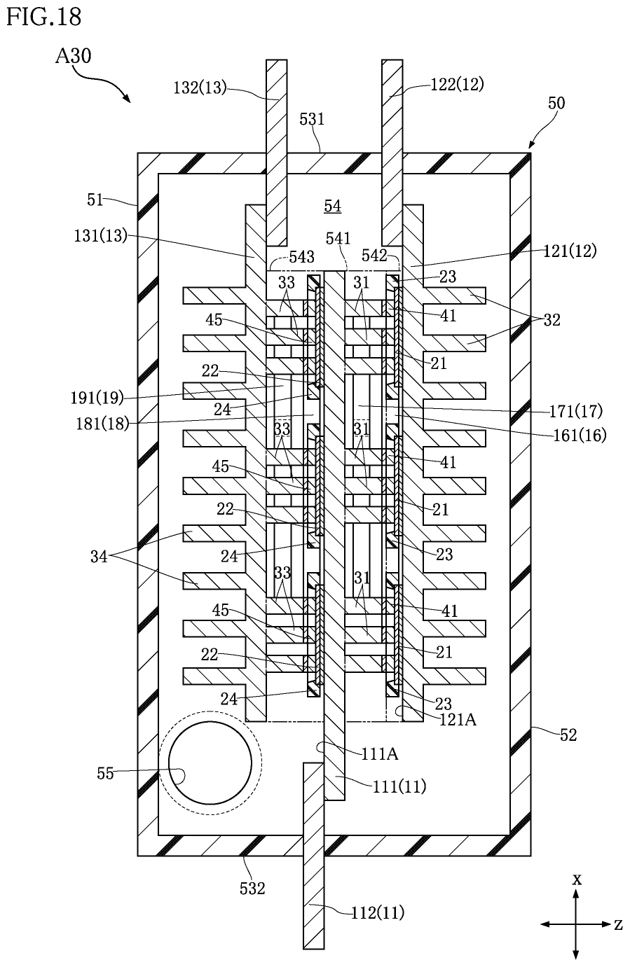

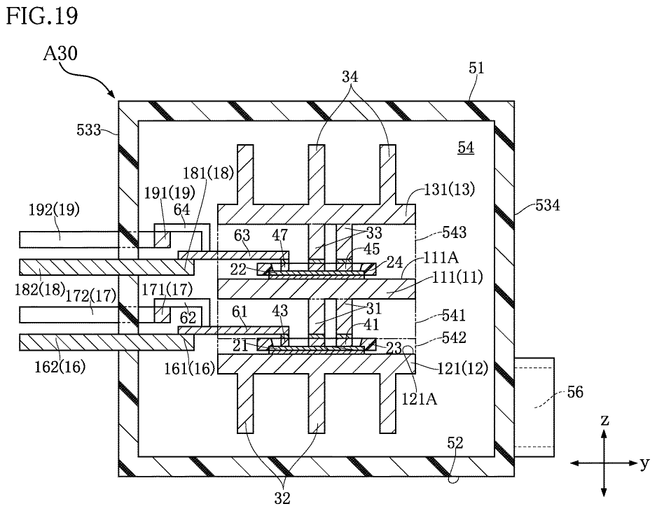

A semiconductor device A30 according to a third embodiment of the present disclosure will be described based on FIGS. 18 to 20. In these figures, the elements that are identical or similar to those of the semiconductor device A10 described above are denoted by the same reference signs, and the descriptions thereof are omitted. FIG. 18 corresponds to FIG. 7, which shows the semiconductor device A10. FIG. 19 corresponds to FIG. 8, which shows the semiconductor device A10.

The semiconductor device A30 differs from the semiconductor device A10 in the configurations of the first protective layers 23 and the second protective layers 24. The semiconductor device A30 does not include the second pillars 42 and the fourth pillars 46.

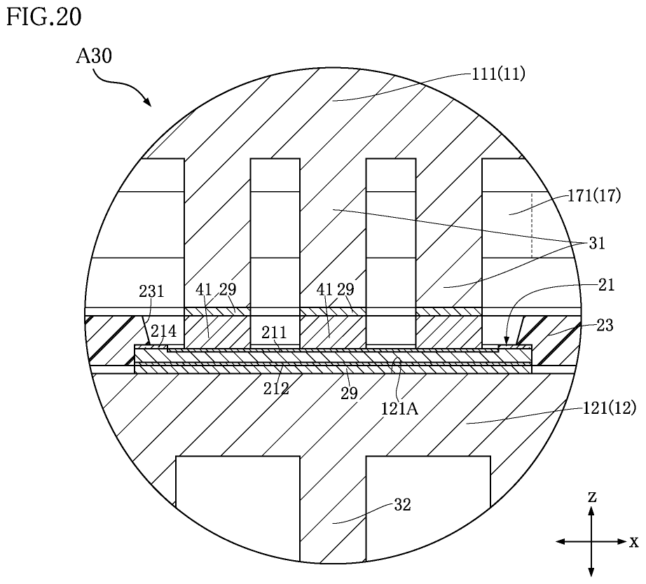

As shown in FIG. 20, the first protective layers 23 do not have the second openings 232. The second electrode 212 of each of the first semiconductor elements 21 is exposed from one side in the first direction z of one of the first protective layers 23. The second electrode 212 of each of the first semiconductor elements 21 is conductively bonded to the first mounting surface 121A of the second base portion 121 of the second terminal 12 via a bonding layer 29.

As with the case of the first protective layers 23, the second protective layers 24 do not have the fourth openings 242. The fourth electrode 222 of each of the second semiconductor elements 22 is exposed from one side in the first direction z of one of the second protective layers 24. The fourth electrode 222 of each of the second semiconductor elements 22 is conductively bonded to the second mounting surface 111A of the first base portion 111 of the first terminal 11 via a bonding layer 29.

Next, the effects of the semiconductor device A30 will be described.

The semiconductor device A30 includes the first semiconductor elements 21, the first terminal 11, the first pillars 41, and the first heat dissipation members 31. The first pillars 41 are electrically connected to the first electrodes 211 of the first semiconductor elements 21. The first heat dissipation members 31 are electrically connected to the first terminal 11. In the first direction z, the first flow path 541 is provided between the first semiconductor elements 21 and the first terminal 11. The first pillars 41 and the first heat dissipation members 31 are housed in the first flow path 541. The first heat dissipation members 31 are conductively bonded to the first pillars 41. Therefore, with the present configuration, the semiconductor device A30 is also capable of improving cooling efficiency. Furthermore, the semiconductor device A30 has a configuration in common with the semiconductor device A10, thereby achieving the same effect as the semiconductor device A10.

In the semiconductor device A30, the second electrodes 212 of the first semiconductor element 21 are conductively bonded to the second terminal 12. With such a configuration, the length of the conductive path between the second terminal 12 and the second electrodes 212 is shortened. This enables the reduction of parasitic inductance in the semiconductor device A30.

### Fourth Embodiment

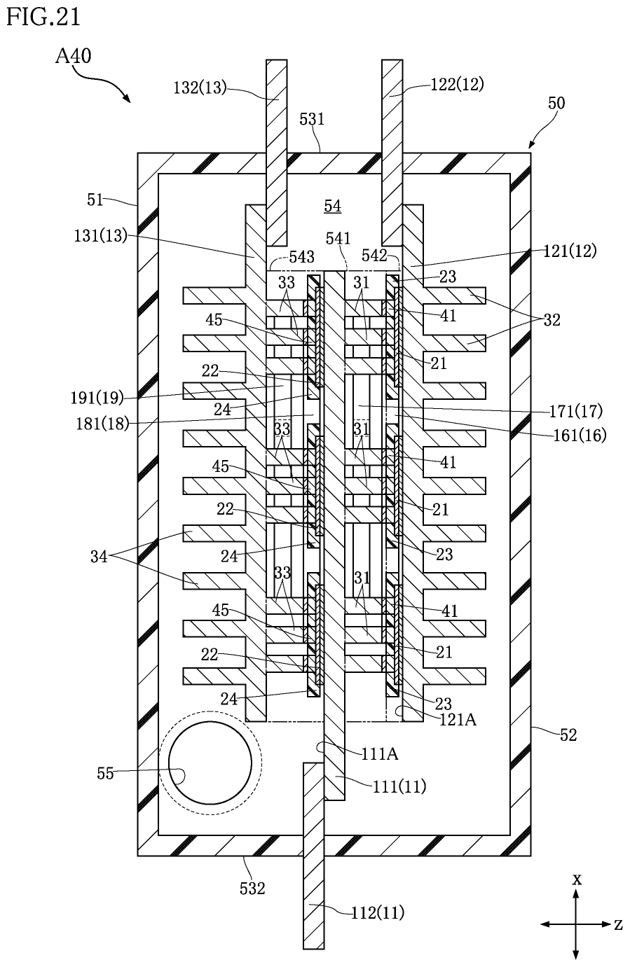

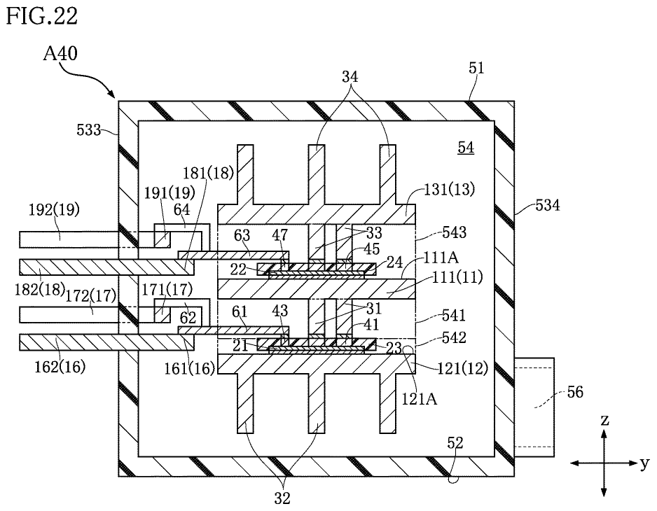

A semiconductor device A40 according to a fourth embodiment of the present disclosure will be described based on FIGS. 21 to 23. In these figures, the elements that are identical or similar to those of the semiconductor device A10 described above are denoted by the same reference signs, and the descriptions thereof are omitted. FIG. 21 corresponds to FIG. 7, which shows the semiconductor device A10. FIG. 22 corresponds to FIG. 8, which shows the semiconductor device A10.

The semiconductor device A40 differs from the semiconductor device A30 in the configurations of the first pillars 41 and the third pillars 45.

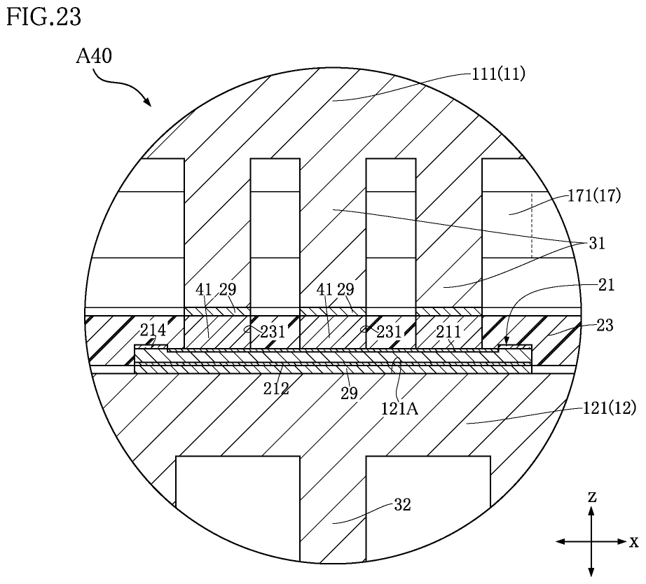

As shown in FIGS. 21 and 22, a part of each of the first pillars 41 is covered with one of the first protective layers 23. A part of each of the third pillars 45 is covered with one of the second protective layers 24. As shown in FIG. 23, in each of the first protective layers 23, the first opening 231 includes a plurality of regions spaced apart from each other in the second direction x. The first pillars 41 are individually housed in these regions.

Next, the effects of the semiconductor device A40 will be described.

The semiconductor device A40 includes the first semiconductor elements 21, the first terminal 11, the first pillars 41, and the first heat dissipation members 31. The first pillars 41 are electrically connected to the first electrodes 211 of the first semiconductor elements 21. The first heat dissipation members 31 are electrically connected to the first terminal 11. In the first direction z, the first flow path 541 is provided between the first semiconductor elements 21 and the first terminal 11. The first pillars 41 and the first heat dissipation members 31 are housed in the first flow path 541. The first heat dissipation members 31 are conductively bonded to the first pillars 41. Therefore, with the present configuration, the semiconductor device A40 is also capable of improving cooling efficiency. Furthermore, the semiconductor device A40 has a configuration in common with the semiconductor device A10, thereby achieving the same effect as the semiconductor device A10.

### Fifth Embodiment

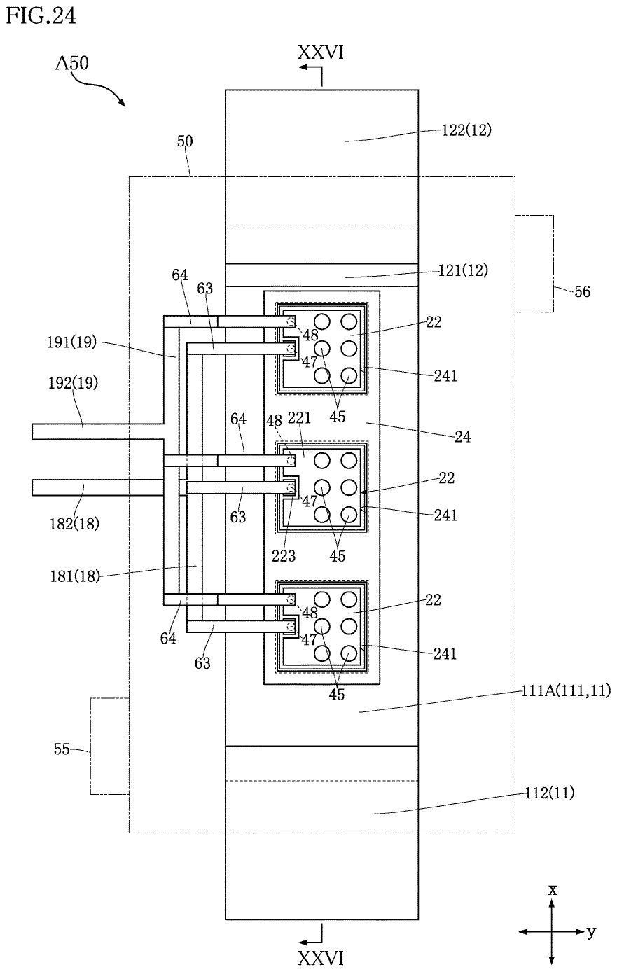

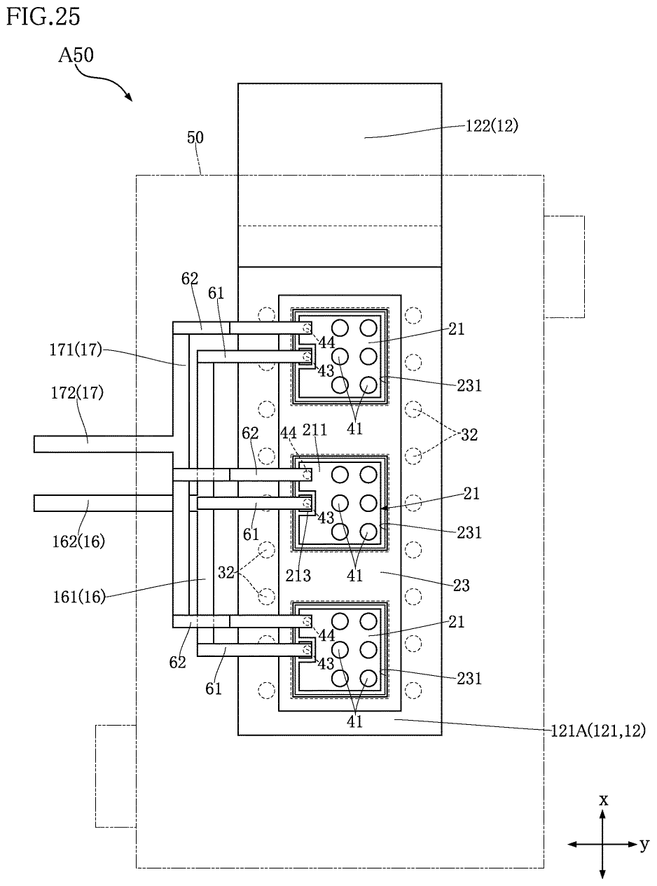

A semiconductor device A50 according to a fifth embodiment of the present disclosure will be described based on FIGS. 24 to 26. In these figures, the elements that are identical or similar to those of the semiconductor device A10 described above are denoted by the same reference signs, and the descriptions thereof are omitted. FIG. 24 corresponds to FIG. 3, which shows the semiconductor device A10. FIG. 25 corresponds to FIG. 5, which shows the semiconductor device A10.

The semiconductor device A50 differs from the semiconductor device A10 in the configuration of the first protective layers 23 and the second protective layers 24.

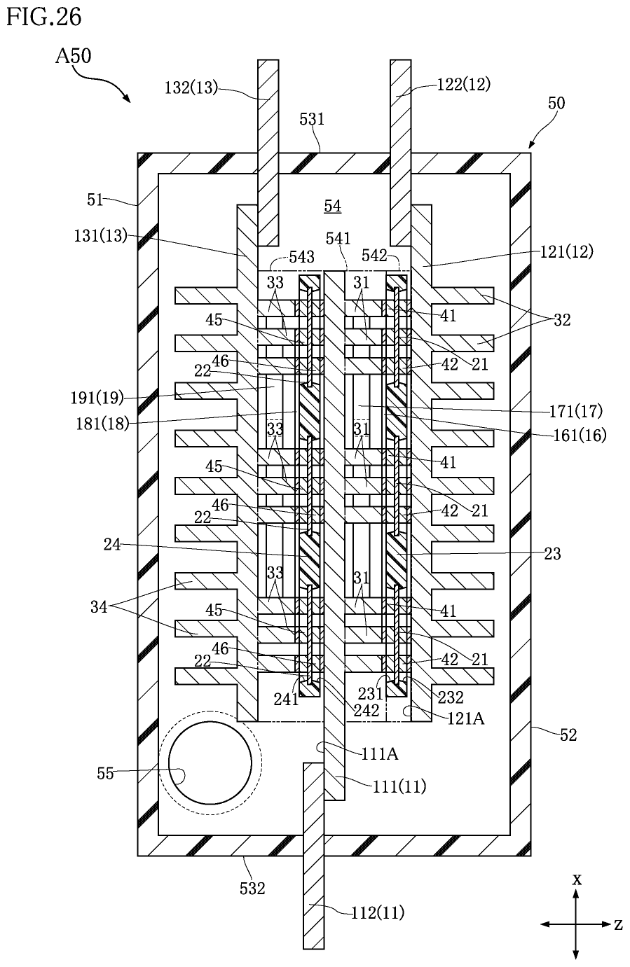

As shown in FIGS. 25 and 26, the first protective layers 23 are connected to each other in the second direction x to form a single member. As shown in FIGS. 24 and 26, the second protective layers 24 are also connected to each other in the second direction x to form a single member.

Next, the effects of the semiconductor device A50 will be described.

The semiconductor device A50 includes the first semiconductor elements 21, the first terminal 11, the first pillars 41, and the first heat dissipation members 31. The first pillars 41 are electrically connected to the first electrodes 211 of the first semiconductor elements 21. The first heat dissipation members 31 are electrically connected to the first terminal 11. In the first direction z, the first flow path 541 is provided between the first semiconductor elements 21 and the first terminal 11. The first pillars 41 and the first heat dissipation members 31 are housed in the first flow path 541. The first heat dissipation members 31 are conductively bonded to the first pillars 41. Therefore, with the present configuration, the semiconductor device A50 is also capable of improving cooling efficiency. Furthermore, the semiconductor device A50 has a configuration in common with the semiconductor device A10, thereby achieving the same effect as the semiconductor device A10.

In the semiconductor device A50, the first protective layers 23 are connected to each other to form a single member. With such a configuration, the first semiconductor elements 21 are encapsulated by a single first protective layer 23. This suppresses positional misalignment of the first semiconductor elements 21 relative to the first terminal 11 and the second terminal 12 during the manufacturing of the semiconductor device A50.

### Sixth Embodiment

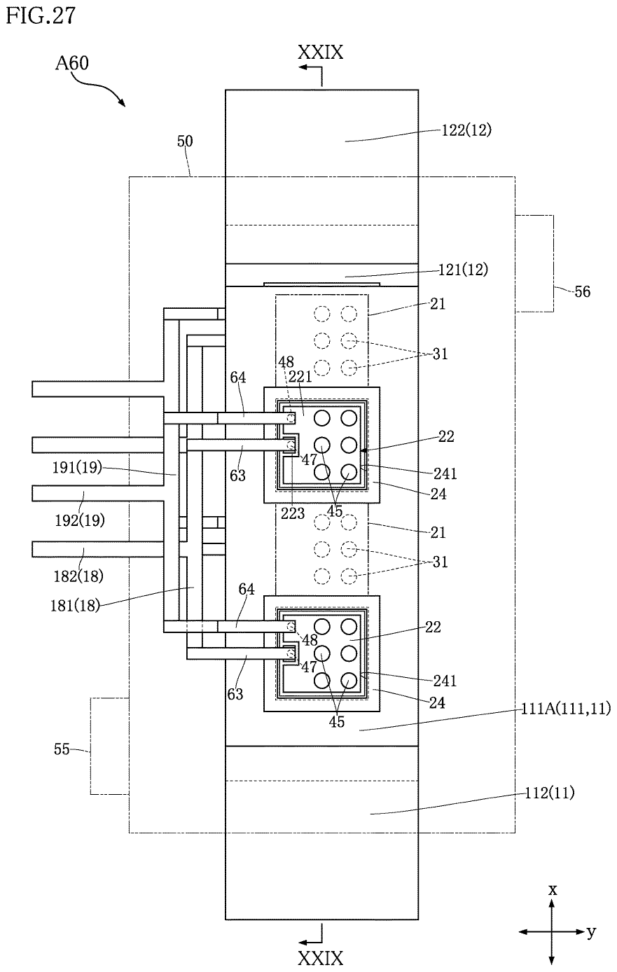

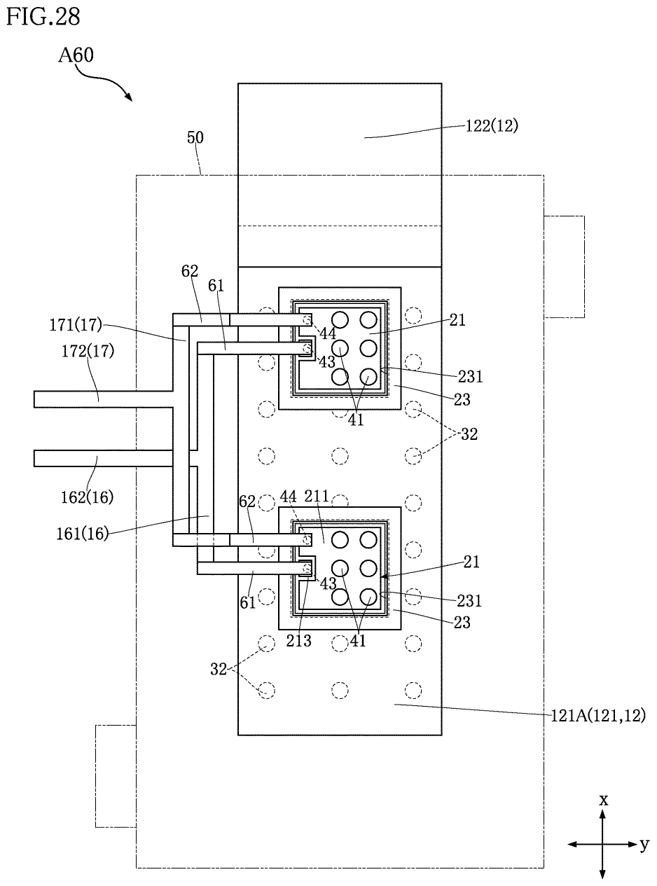

A semiconductor device A60 according to a sixth embodiment of the present disclosure will be described based on FIGS. 27 to 29. In these figures, the elements that are identical or similar to those of the semiconductor device A10 described above are denoted by the same reference signs, and the descriptions thereof are omitted. FIG. 27 corresponds to FIG. 3, which shows the semiconductor device A10. FIG. 28 corresponds to FIG. 5, which shows the semiconductor device A10.

The semiconductor device A60 differs from the semiconductor device A10 in the configuration of the first semiconductor elements 21 and the second semiconductor elements 22.

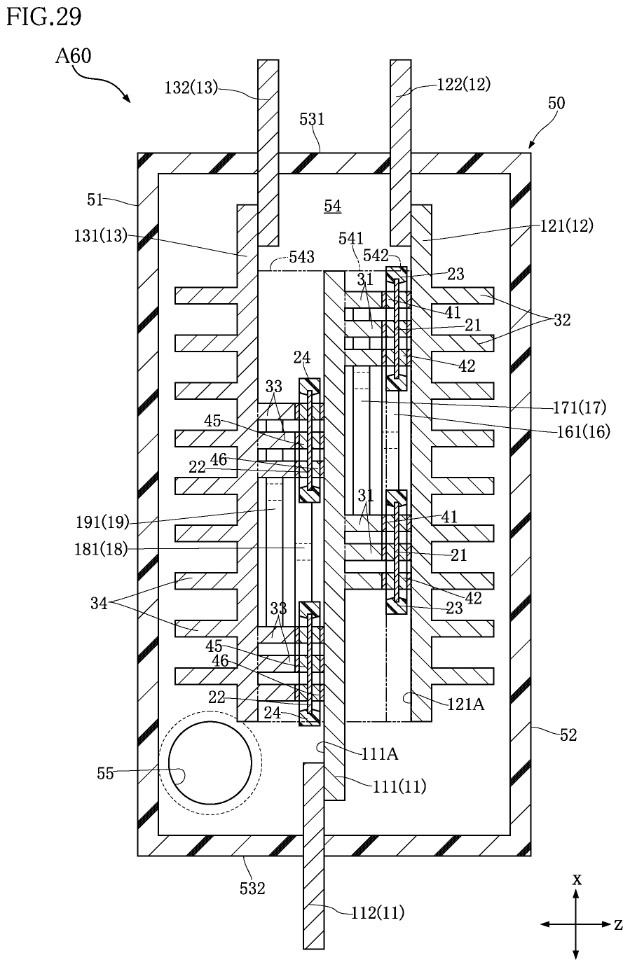

As shown in FIGS. 27 and 28, the number of first semiconductor elements 21 and the number of second semiconductor elements 22 are both two. As shown in FIGS. 27 and 29, as viewed in the first direction z, each of the second semiconductor elements 22 is spaced apart from the first semiconductor elements 21.

Next, the effects of the semiconductor device A60 will be described.

The semiconductor device A60 includes the first semiconductor elements 21, the first terminal 11, the first pillars 41, and the first heat dissipation members 31. The first pillars 41 are electrically connected to the first electrodes 211 of the first semiconductor elements 21. The first heat dissipation members 31 are electrically connected to the first terminal 11. In the first direction z, the first flow path 541 is provided between the first semiconductor elements 21 and the first terminal 11. The first pillars 41 and the first heat dissipation members 31 are housed in the first flow path 541. The first heat dissipation members 31 are conductively bonded to the first pillars 41. Therefore, with the present configuration, the semiconductor device A60 is also capable of improving cooling efficiency. Furthermore, the semiconductor device A60 has a configuration in common with the semiconductor device A10, thereby achieving the same effect as the semiconductor device A10.

In the semiconductor device A60, as viewed in the first direction z, the second semiconductor elements 22 are spaced apart from the first semiconductor elements 21. Such a configuration reduces the concentration in the heat distribution at the first terminal 11 caused by the heat generation of the first semiconductor elements 21 and the second semiconductor elements 22.

### Seventh Embodiment

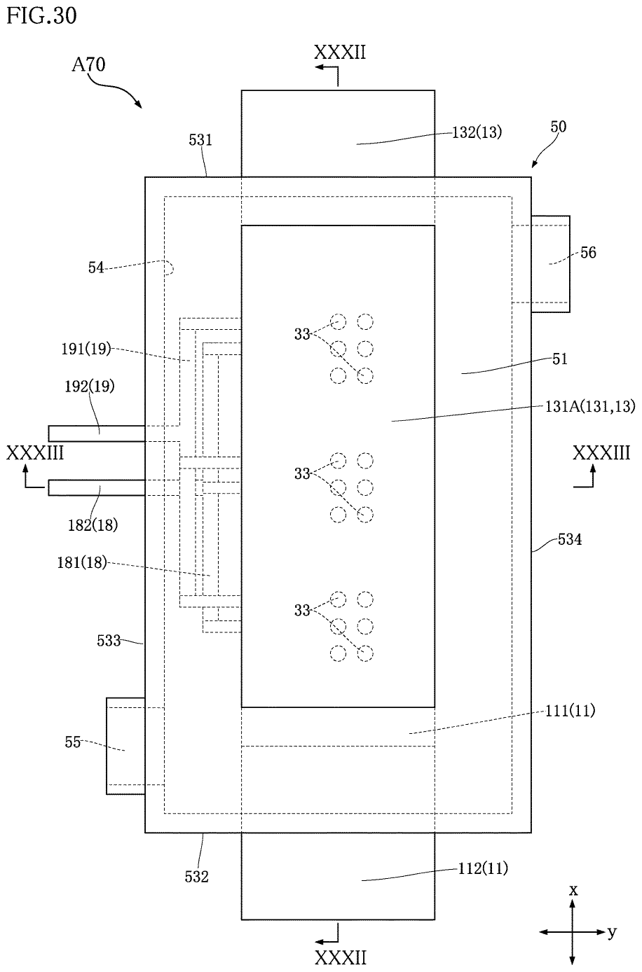

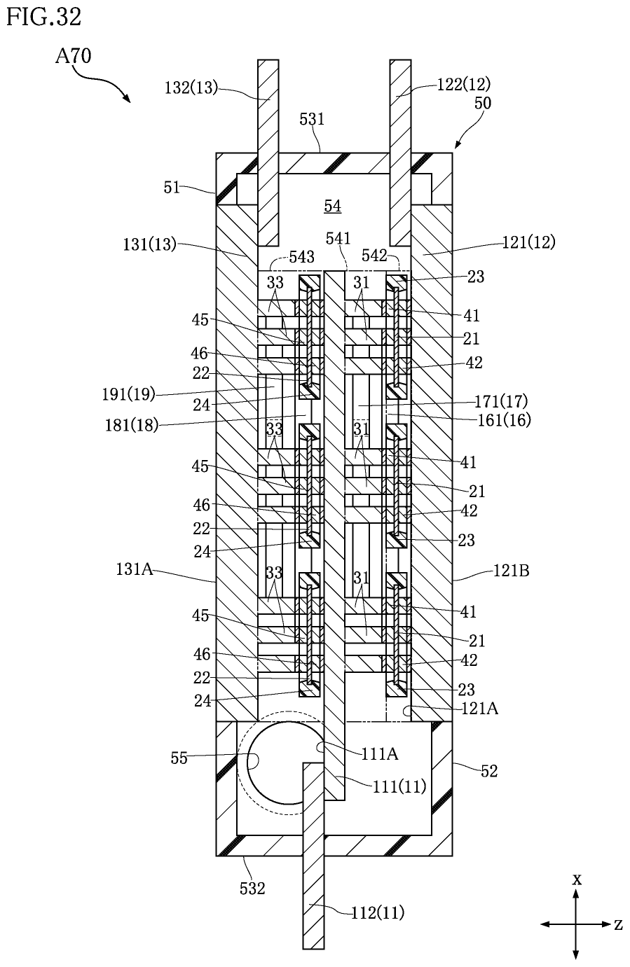

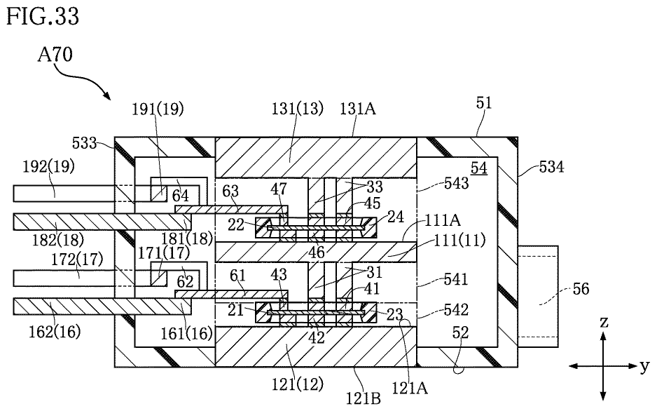

A semiconductor device A70 according to a seventh embodiment of the present disclosure will be described based on FIGS. 30 to 33. In these figures, the elements that are identical or similar to those of the semiconductor device A10 described above are denoted by the same reference signs, and the descriptions thereof are omitted.

The semiconductor device A70 differs from the semiconductor device A10 in the configurations of the second terminal 12 and the third terminal 13. Furthermore, the semiconductor device A70 does not include the second heat dissipation members 32 and the fourth heat dissipation members 34.

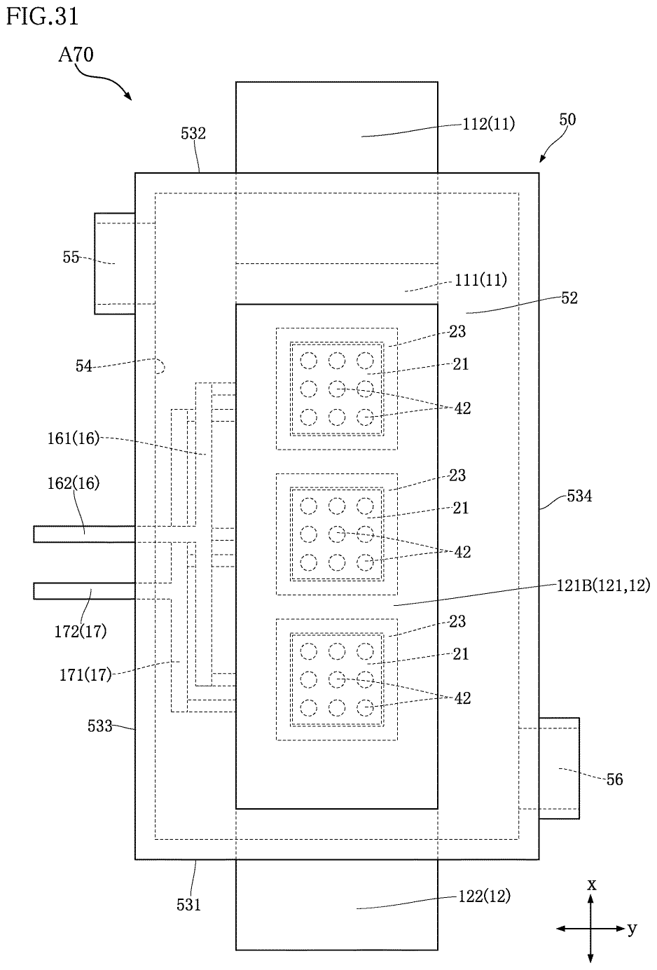

As shown in FIGS. 31 to 33, the second base portion 121 of the second terminal 12 has a first exposed surface 121B facing away from the side where the first semiconductor elements 21 are located in the first direction z. The first exposed surface 121B is exposed from the bottom surface 52 of the housing 50. The dimension of the second base portion 121 in the first direction z is larger than the dimension of the first base portion 111 of the first terminal 11 in the first direction z.

As shown in FIGS. 30, 32, and 33, the third base portion 131 of the third terminal 13 has a second exposed surface 131A facing away from the side where the second semiconductor elements 22 are located in the first direction z. The second exposed surface 131A is exposed from the top surface 51 of the housing 50. The dimension of the third base portion 131 in the first direction z is larger than the dimension of the first base portion 111 of the first terminal 11 in the first direction z.

Next, the effects of the semiconductor device A70 will be described.

The semiconductor device A70 includes the first semiconductor elements 21, the first terminal 11, the first pillars 41, and the first heat dissipation members 31. The first pillars 41 are electrically connected to the first electrodes 211 of the first semiconductor elements 21. The first heat dissipation members 31 are electrically connected to the first terminal 11. In the first direction z, the first flow path 541 is provided between the first semiconductor elements 21 and the first terminal 11. The first pillars 41 and the first heat dissipation members 31 are housed in the first flow path 541. The first heat dissipation members 31 are conductively bonded to the first pillars 41. Therefore, with the present configuration, the semiconductor device A70 is also capable of improving cooling efficiency. Furthermore, the semiconductor device A70 has a configuration in common with the semiconductor device A10, thereby achieving the same effect as the semiconductor device A10.

In the semiconductor device A70, the second terminal 12 has the first exposed surface 121B facing away from the side where the first semiconductor elements 21 are located in the first direction z. The third terminal 13 has the second exposed surface 131A facing away from the side where the second semiconductor elements 22 are located in the first direction z. The first exposed surface 121B and the second exposed surface 131A are exposed from the housing 50. With such a configuration, the dimension of the semiconductor device A70 in the first direction z can be reduced.

### Eighth Embodiment

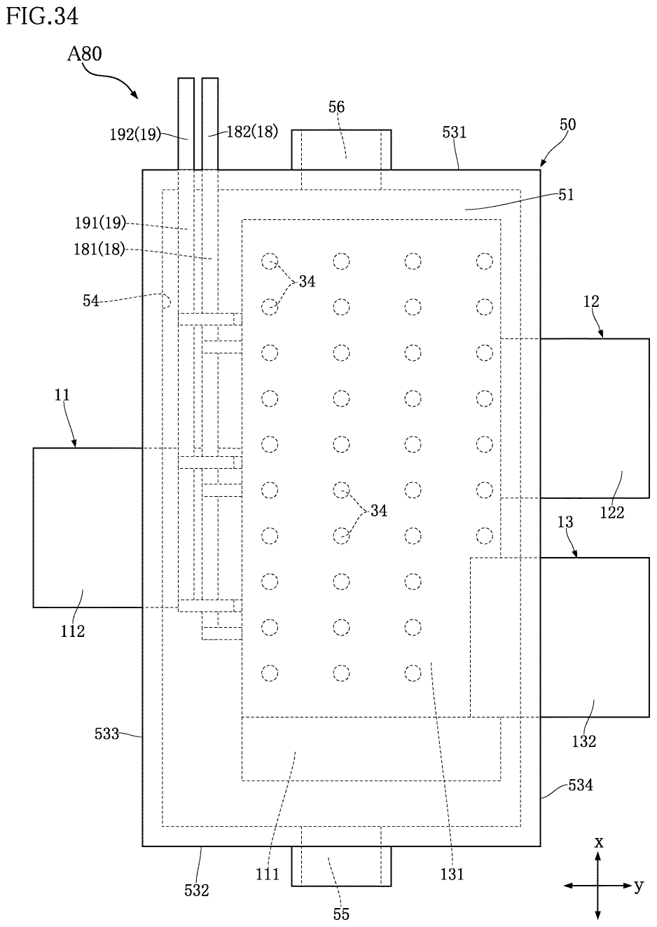

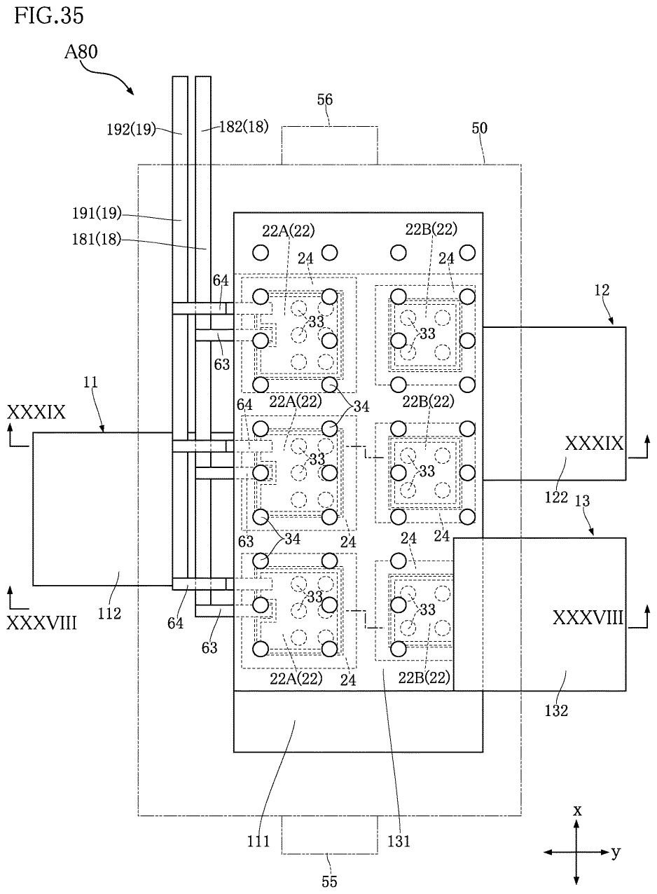

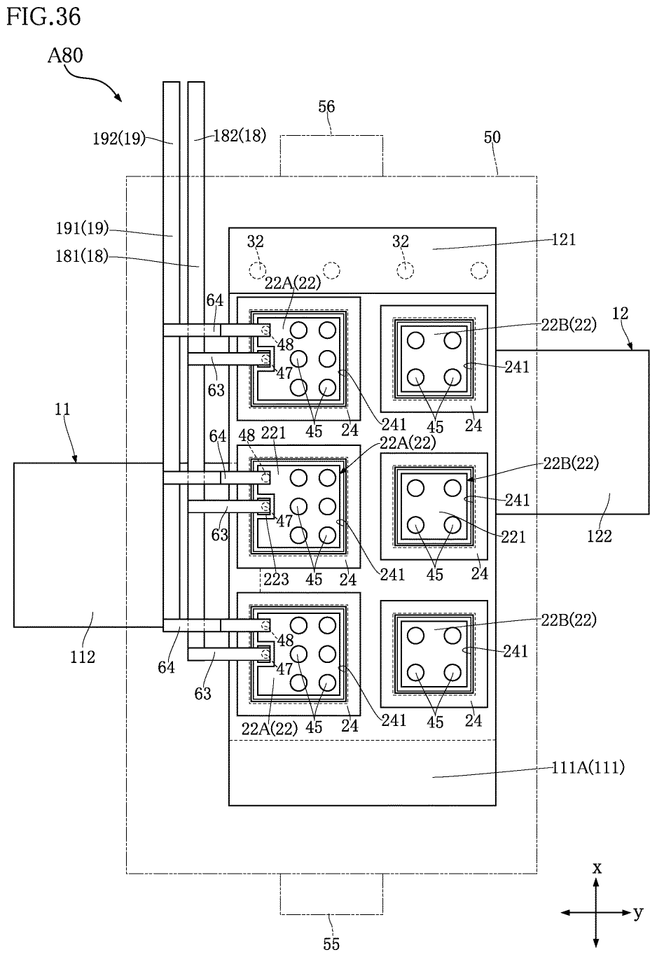

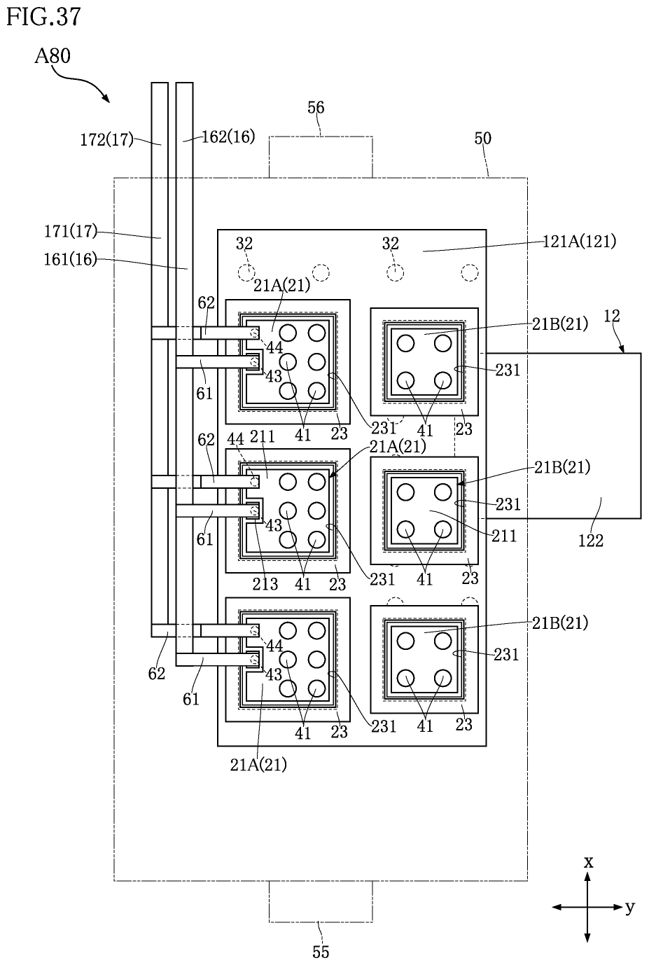

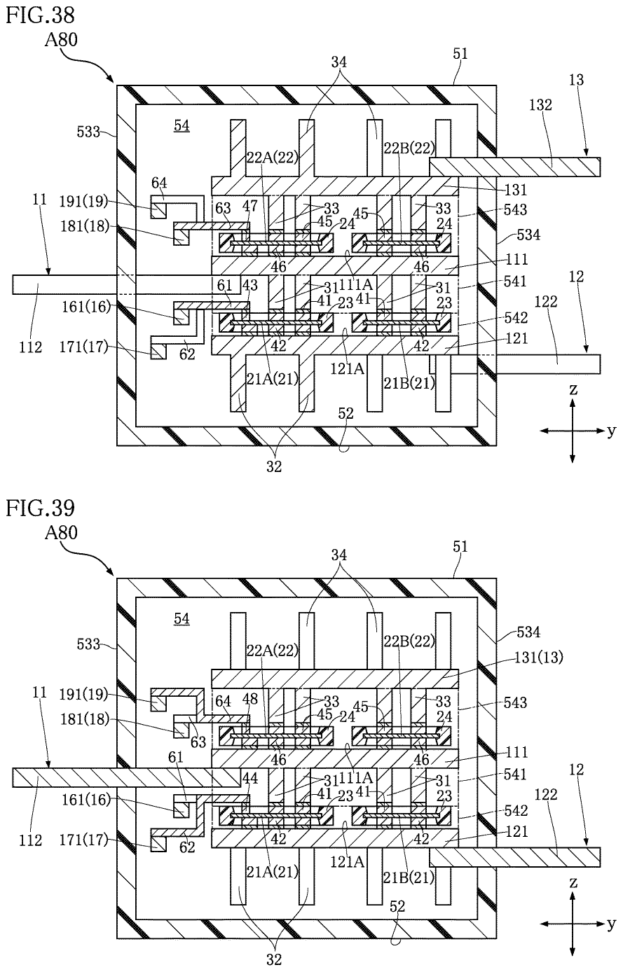

A semiconductor device A80 according to an eighth embodiment of the present disclosure will be described based on FIGS. 34 to 39. In these figures, the elements that are identical or similar to those of the semiconductor device A10 described above are denoted by the same reference signs, and the descriptions thereof are omitted. FIG. 35 corresponds to FIG. 2, which shows the semiconductor device A10. FIG. 36 corresponds to FIG. 3, which shows the semiconductor device A10. FIG. 37 corresponds to FIG. 5, which shows the semiconductor device A10.

The semiconductor device A80 differs from the semiconductor device A10 in the configurations of the first terminal 11, the second terminal 12, the third terminal 13, the first signal terminal 16, the second signal terminal 17, the third signal terminal 18, the fourth signal terminal 19, the housing 50, the first semiconductor elements 21, and the second semiconductor elements 22.

As shown in FIGS. 36 and 39, the first extension portion 112 of the first terminal 11 is located on one side of the first base portion 111 in the third direction y. As shown in FIGS. 34 and 39, a part of the first extension portion 112 protrudes outward from the third side surface 533 of the housing 50.

As shown in FIGS. 35, 37, and 38, the second extension portion 122 of the second terminal 12 and the third extension portion 132 of the third terminal 13 are located opposite the first extension portion 112 of the first terminal 11 with respect to the first semiconductor elements 21 and the second semiconductor elements 22 in the third direction y. As shown in FIGS. 34, 38, and 39, a part of each of the second extension portion 122 and the third extension portion 132 protrudes outward from the fourth side surface 534 of the housing 50. The second extension portion 122 and the third extension portion 132 are spaced apart from each other in the second direction x.

As shown in FIG. 37, the outer portion 162 of the first signal terminal 16 and the outer portion 172 of the second signal terminal 17 protrude outward from the first side surface 531 of the housing 50. As shown in FIG. 34, the outer portion 182 of the third signal terminal 18 and the outer portion 192 of the fourth signal terminal 19 protrude outward from the first side surface 531.

As shown in FIG. 34, the inlet 55 of the housing 50 is open at the second side surface 532 of the housing 50. The outlet 56 of the housing 50 is open at the first side surface 531.

As shown in FIGS. 37 to 39, the plurality of first semiconductor elements 21 include a plurality of first switching elements 21A and a plurality of first diodes 21B. The first diodes 21B are individually connected in parallel to the first switching elements 21A. Each of the first switching elements 21A has the first electrode 211, the second electrode 212, and the first gate electrode 213. The first switching elements 21A are transistors, such as MOSFETs or IGBTs. In the semiconductor device A80, the first switching elements 21A are, for example, MOSFETs. The first diodes 21B have the first electrodes 211 serving as the anodes and the second electrodes 212 serving as the cathodes. In the semiconductor device A80, the first diodes 21B function as freewheeling diodes for the first switching elements 21A. In the semiconductor device A80, the first diodes 21B are, for example, Schottky barrier diodes. Each of the first pillars 41 is electrically connected to the first electrode 211 of one of the first switching elements 21A or one of the first diodes 21B. Each of the second pillars 42 is electrically connected to the second electrode 212 of one of the first switching elements 21A or one of the first diodes 21B.

As shown in FIGS. 36, 38, and 39, the plurality of second semiconductor elements 22 include a plurality of second switching elements 22A and a plurality of second diodes 22B. The second diodes 22B are individually connected in parallel to the second switching elements 22A. Each of the second switching elements 22A has the third electrode 221, the fourth electrode 222, and the second gate electrode 223. The second switching elements 22A are identical to the first switching elements 21A. The second diodes 22B have the third electrodes 221 serving as the anodes and the fourth electrodes 222 serving as the cathodes. In the semiconductor device A80, the second diodes 22B function as freewheeling diodes for the second switching elements 22A. The second diodes 22B are identical to the first diodes 21B. Each of the third pillars 45 is electrically connected to the third electrode 221 of one of the second switching elements 22A or one of the second diodes 22B. Each of the fourth pillars 46 is electrically connected to the fourth electrode 222 of one of the second switching elements 22A or one of the second diodes 22B.

In this way, like the semiconductor device A80, the plurality of first semiconductor elements 21 may not all be identical elements but may include a plurality of types of elements. Similarly, the plurality of second semiconductor elements 22 may not all be identical elements but may include a plurality of types of elements.

Next, the effects of the semiconductor device A80 will be described.

The semiconductor device A80 includes the first semiconductor elements 21, the first terminal 11, the first pillars 41, and the first heat dissipation members 31. The first pillars 41 are electrically connected to the first electrodes 211 of the first semiconductor elements 21. The first heat dissipation members 31 are electrically connected to the first terminal 11. In the first direction z, the first flow path 541 is provided between the first semiconductor elements 21 and the first terminal 11. The first pillars 41 and the first heat dissipation members 31 are housed in the first flow path 541. The first heat dissipation members 31 are conductively bonded to the first pillars 41. Therefore, with the present configuration, the semiconductor device A80 is also capable of improving cooling efficiency. Furthermore, the semiconductor device A80 has a configuration in common with the semiconductor device A10, thereby achieving the same effect as the semiconductor device A10.

The present disclosure is not limited to the above-described embodiments. Various modifications in design may be made freely in the specific structure of each part of the present disclosure.

The present disclosure includes embodiments described in the following clauses.

### Clause 1

A semiconductor device comprising:
a first semiconductor element including a first electrode located on one side in a first direction;
a first terminal facing the first electrode;
a first pillar electrically connected to the first electrode; and
a first heat dissipation member electrically connected to the first terminal, wherein
a first flow path is provided between the first semiconductor element and the first terminal in the first direction,
the first pillar and the first heat dissipation member are housed in the first flow path, and
the first heat dissipation member is conductively bonded to the first pillar.

### Clause 2

The semiconductor device according to clause 1, further comprising a first protective layer that is an insulator,
wherein the first protective layer covers at least a part of the first semiconductor element.

### Clause 3

The semiconductor device according to clause 2, wherein the first protective layer includes a first opening through which the first electrode is exposed, and
at least a part of the first pillar is housed in the first opening.

### Clause 4

The semiconductor device according to clause 3, wherein the first terminal is in contact with the first flow path.

### Clause 5

The semiconductor device according to clause 4, wherein a dimension of the first pillar in the first direction is smaller than a dimension of the first heat dissipation member in the first direction.

### Clause 6

The semiconductor device according to clause 5, wherein the first electrode is in contact with the first flow path.

### Clause 7

The semiconductor device according to clause 6, wherein a size of a cross section of the first opening taken orthogonal to the first direction increases from the first electrode toward the first heat dissipation member.

### Clause 8

The semiconductor device according to clause 5, wherein a part of the first pillar is covered with the first protective layer.

### Clause 9

The semiconductor device according to any one of clauses 3 to 8, further comprising a second terminal located opposite the first terminal with respect to the first semiconductor element,
wherein the first semiconductor element includes a second electrode located opposite the first electrode in the first direction and electrically conducting to the second terminal.

### Clause 10

The semiconductor device according to clause 9, wherein a second flow path is provided between the second terminal and the first flow path in the first direction,
the second flow path is connected to the first flow path, and
the second terminal is in contact with the second flow path.

### Clause 11

The semiconductor device according to clause 10, wherein the first protective layer covers an entire periphery of the first semiconductor element as viewed in the first direction.

### Clause 12

The semiconductor device according to clause 11, further comprising a second pillar electrically connected to the second electrode, wherein
the second pillar is conductively bonded to the second terminal, and
the second pillar is housed in the second flow path.

### Clause 13

The semiconductor device according to clause 12, wherein the first protective layer includes a second opening through which the second electrode is exposed, and
at least a part of the second pillar is housed in the second opening.

### Clause 14

The semiconductor device according to clause 13, wherein a part of the second flow path is located between the second terminal and the first protective layer in the first direction.

### Clause 15

The semiconductor device according to clause 14, wherein the second electrode is in contact with the second flow path.

### Clause 16

The semiconductor device according to clause 15, wherein the first protective layer is spaced apart from the second terminal.

### Clause 17

The semiconductor device according to clause 11, wherein the second electrode is conductively bonded to the second terminal.

### Clause 18

The semiconductor device according to clause 10, further comprising a housing, wherein
the first terminal and the second terminal are supported by the housing, and
the housing includes a hollow portion including the first flow path and the second flow path.

### Clause 19

The semiconductor device according to clause 18, further comprising a second heat dissipation member connected to the second terminal, wherein
the second heat dissipation member is located opposite the first semiconductor element with respect to the second terminal, and
the second heat dissipation member is housed in the hollow portion.

### Clause 20

A vehicle comprising:
a driving source; and
the semiconductor device as set forth in clause 9,
wherein the semiconductor device electrically conducts to the driving source.

### Clause 21

The semiconductor device according to clause 9, further comprising a first signal terminal, wherein
the first semiconductor element includes a first gate electrode located on a same side as the first electrode in the first direction, and
the first gate electrode electrically conducts to the first signal terminal.

### Clause 22

The semiconductor device according to clause 10, further comprising a second semiconductor element located opposite the first semiconductor element with respect to the first terminal,
wherein the second semiconductor element electrically conducts to the first terminal.

### Clause 23

The semiconductor device according to clause 22, wherein the second semiconductor element overlaps with the first semiconductor element as viewed in the first direction.

### Clause 24

The semiconductor device according to clause 22, wherein the second semiconductor element is spaced apart from the first semiconductor element as viewed in the first direction.

### Clause 25

The semiconductor device according to clause 22, further comprising a third terminal located opposite the first terminal with respect to the second semiconductor element, wherein
the second semiconductor element electrically conducts to the third terminal,
a third flow path is provided between the first terminal and the third terminal in the first direction, and
the second semiconductor element is housed in the third flow path.

### Clause 26

The semiconductor device according to clause 25, wherein the second terminal and the third terminal are in contact with the third flow path.

### Clause 27

The semiconductor device according to clause 26, further comprising a third head dissipation member electrically connected to the third terminal, wherein
the second semiconductor element electrically conducts to the third head dissipation member, and
the third head dissipation member is housed in the third flow path.

### Clause 28

The semiconductor device according to clause 27, further comprising a fourth heat dissipation member connected to the third terminal,
wherein the fourth heat dissipation member is located opposite the third head dissipation member with respect to the third terminal.

### Clause 29

The semiconductor device according to clause 11, wherein the first semiconductor element includes a first protective film located on a same side as the first electrode in the first direction,
the first protective film surrounds a periphery of the first electrode as viewed in the first direction, and
the first protective layer covers a part of the first protective film.

### Clause 30

The semiconductor device according to clause 16, wherein a dimension of the second pillar in the first direction is larger than a dimension of the first pillar in the first direction.

### Clause 31

The semiconductor device according to clause 18, wherein the housing includes an inlet and an outlet each communicating with the hollow portion, and
the inlet and the outlet are located on opposite sides of each other with respect to the first heat dissipation member in a direction orthogonal to the first direction.

### Clause 32

The semiconductor device according to clause 31, wherein the second terminal includes a first exposed surface facing away from a side where the first semiconductor element is located in the first direction, and
the first exposed surface is exposed from the housing.

### REFERENCE NUMERALS

A10 to A80: Semiconductor device B: Vehicle
11: First terminal 111: First base portion
111A: Second mounting surface 112: First extension portion
12: Second terminal 121: Second base portion
121A: Second mounting surface 121B: First exposed surface
122: Second extension portion 13: Third terminal
131: Third base portion 131A: Second exposed surface
132: Third extension portion 16: First signal terminal
161: Inner portion 162: Outer portion
17: Second signal terminal 171: Inner portion
172: Outer portion 18: Third signal terminal
181: Inner portion 182: Outer portion
19: Fourth signal terminal 191: Inner portion
192: Outer portion 21: First semiconductor element
21A: First switching element 21B: First diode
211: First electrode 212: Second electrode
213: First gate electrode 214: First protective film
22: Second semiconductor element 22A: Second switching element
22B: Second diode 221: Third electrode
222: Fourth electrode 223: Second gate electrode
224: Second protective film 23: First protective layer
231: First opening 232: Second opening
24: Second protective layer 241: Third opening
242: Fourth opening 29: Bonding layer
31: First heat dissipation member 32: Second heat dissipation member
33: Third head dissipation member 34: Fourth heat dissipation member
41: First pillar 42: Second pillar
43: First gate pillar 44: First detection pillar
45: Third pillar 46: Fourth pillar
47: Second gate pillar 48: Second detection pillar
50: Housing 51: Top surface
52: Bottom surface 531 to 534: First side surface to fourth side surface
54: Hollow portion 541 to 543: First flow path to third flow path
55: Inlet 56: Outlet
61 to 64: First lead to fourth lead 70: Coolant
81: On-board charger 82: Storage battery
83: Drive system 831: Inverter
832: Driving source z: First direction
x: Second direction y: Third direction

1. A semiconductor device comprising:
a first semiconductor element including a first electrode located on one side in a first direction;
a first terminal facing the first electrode;
a first pillar electrically connected to the first electrode; and
a first heat dissipation member electrically connected to the first terminal, wherein
a first flow path is provided between the first semiconductor element and the first terminal in the first direction,
the first pillar and the first heat dissipation member are housed in the first flow path, and
the first heat dissipation member is conductively bonded to the first pillar.

2. The semiconductor device according to claim 1, further comprising a first protective layer that is an insulator,
wherein the first protective layer covers at least a part of the first semiconductor element.

3. The semiconductor device according to claim 2, wherein the first protective layer includes a first opening through which the first electrode is exposed, and
at least a part of the first pillar is housed in the first opening.

4. The semiconductor device according to claim 3, wherein the first terminal is in contact with the first flow path.

5. The semiconductor device according to claim 4, wherein a dimension of the first pillar in the first direction is smaller than a dimension of the first heat dissipation member in the first direction.

6. The semiconductor device according to claim 5, wherein the first electrode is in contact with the first flow path.

7. The semiconductor device according to claim 6, wherein a size of a cross section of the first opening taken orthogonal to the first direction increases from the first electrode toward the first heat dissipation member.

8. The semiconductor device according to claim 5, wherein a part of the first pillar is covered with the first protective layer.

9. The semiconductor device according to claim 3, further comprising a second terminal located opposite the first terminal with respect to the first semiconductor element,
wherein the first semiconductor element includes a second electrode located opposite the first electrode in the first direction and electrically conducting to the second terminal.

10. The semiconductor device according to claim 9, wherein a second flow path is provided between the second terminal and the first flow path in the first direction,
the second flow path is connected to the first flow path, and
the second terminal is in contact with the second flow path.

11. The semiconductor device according to claim 10, wherein the first protective layer covers an entire periphery of the first semiconductor element as viewed in the first direction.

12. The semiconductor device according to claim 11, further comprising a second pillar electrically connected to the second electrode, wherein
the second pillar is conductively bonded to the second terminal, and
the second pillar is housed in the second flow path.

13. The semiconductor device according to claim 12, wherein the first protective layer includes a second opening through which the second electrode is exposed, and
at least a part of the second pillar is housed in the second opening.

14. The semiconductor device according to claim 13, wherein a part of the second flow path is located between the second terminal and the first protective layer in the first direction.

15. The semiconductor device according to claim 14, wherein the second electrode is in contact with the second flow path.

16. The semiconductor device according to claim 15, wherein the first protective layer is spaced apart from the second terminal.

17. The semiconductor device according to claim 11, wherein the second electrode is conductively bonded to the second terminal.

18. The semiconductor device according to claim 10, further comprising a housing, wherein
the first terminal and the second terminal are supported by the housing, and
the housing includes a hollow portion including the first flow path and the second flow path.

19. The semiconductor device according to claim 18, further comprising a second heat dissipation member connected to the second terminal, wherein
the second heat dissipation member is located opposite the first semiconductor element with respect to the second terminal, and
the second heat dissipation member is housed in the hollow portion.

20. A vehicle comprising:
a driving source; and
the semiconductor device as set forth in claim 9,
wherein the semiconductor device electrically conducts to the driving source.
